(19) United States
(12) Patent Application Publication
(10) Pub. No.: US 2020/0211949 A1
(43) Pub. Date: Jul. 2, 2020

(54) MICROELECTRONIC ASSEMBLIES WITH VIA-TRACE-VIA STRUCTURES

(71) Applicant: Intel Corporation, Santa Clara, CA (US)

(72) Inventors: Veronica Aleman Strong, Hillsboro, OR (US); Aleksandar Aleksov, Chandler, AZ (US)

(73) Assignee: Intel Corporation, Santa Clara, CA (US)

(21) Appl. No.: 16/232,898

(22) Filed: Dec. 26, 2018

(51) Int. Cl. H01L 23/498; H01L 23/66; H01L 23/00; H01L 21/48; H01P 3/06; H01P 11/00; G06F 1/16

(52) U.S. Cl. CPC H01L 23/49838; H01L 23/49822; H01L 23/49894; H01L 23/66; H01L 24/16; H01L 21/4853; H01L 2223/6627; H01P 3/06; H01P 11/005; G06F 1/1613; H01L 2224/16227; H01L 2223/6616; H01L 21/4857

(57) ABSTRACT

Disclosed herein are via-trace-via structures with improved alignment, and related devices and methods. For example, in some embodiments, an integrated circuit (IC) package substrate may include a conductive trace having a first surface and an opposing second surface; a first conductive via in a first dielectric layer, wherein the first conductive via is in contact with the first surface of the conductive trace; and a second conductive via in a second dielectric layer, wherein the second conductive via is in contact with the second surface of the conductive trace, wherein the second dielectric layer is on the first dielectric layer, and wherein the first conductive via, the second conductive via, and the conductive trace have a same width between 0.5 um and 25 um.

### BACKGROUND

Integrated circuit devices are conventionally coupled to a package substrate or interposers for mechanical stability and to facilitate connection to other components via conductive pathways in the package substrate or interposers, such as circuit boards. Conductive pathways generally include a plurality of metal trace layers separated by dielectric layers. Conductive vias provide electrical connections between the metal trace layers.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1A is a side, cross-sectional view of an example microelectronic assembly, in accordance with various embodiments.

FIG. 1B is a magnified portion of a via-trace-via structure of the example microelectronic assembly of FIG. 1A, in accordance with various embodiments.

FIG. 1C is a side, cross-sectional view along the A-A′ line of the example microelectronic assembly of FIG. 1A, in accordance with various embodiments.

FIGS. 2A-2L are side, cross-sectional views of various stages in an example process for manufacturing a microelectronic assembly having the via-trace-via structure of FIG. 1, in accordance with various embodiments.

FIG. 3A is a side, cross-sectional view of an example microelectronic assembly, in accordance with various embodiments.

FIG. 3B is a side, cross-sectional view along the A-A′ line of the example microelectronic assembly of FIG. 3A, in accordance with various embodiments.

FIG. 3C is a side, cross-sectional view along the B-B′ line of the example microelectronic assembly of FIG. 3A, in accordance with various embodiments.

FIGS. 4A-4E are side, cross-sectional views of various stages in an example process for manufacturing a microelectronic assembly having the via-trace-via structure of FIG. 3, in accordance with various embodiments.

FIG. 5A is a side, cross-sectional view of an example microelectronic assembly, in accordance with various embodiments.

FIG. 5B is a magnified portion of a via-trace-via structure of the example microelectronic assembly of FIG. 5A, in accordance with various embodiments.

FIG. 5C is a side, cross-sectional view along the A-A′ line of the example microelectronic assembly of FIG. 5A, in accordance with various embodiments.

FIGS. 6A-6G are side, cross-sectional views of various stages in an example process for manufacturing a microelectronic assembly having the via-trace-via structure of FIG. 5, in accordance with various embodiments.

FIGS. 7A-7F are side, cross-sectional views of various stages in an example process for manufacturing a microelectronic assembly having a via-trace structure of FIG. 5, in accordance with various embodiments.

FIG. 8A is a side, cross-sectional view of an example via-trace-via structure, in accordance with various embodiments.

FIG. 8B is a side, cross-sectional view along the A-A′ line of the example via-trace-via structure of FIG. 8A, in accordance with various embodiments.

FIG. 8C is a side, cross-sectional view along the B-B′ line of the example via-trace-via structure of FIG. 8A, in accordance with various embodiments.

FIG. 9 is a side, cross-sectional view of an example microelectronic assembly having a via-trace-via structure, in accordance with various embodiments.

FIG. 10 is a side, cross-sectional view of another example microelectronic assembly having a via-trace-via structure, in accordance with various embodiments.

FIG. 11 is a side, cross-sectional view of another example microelectronic assembly having a via-trace-via structure, in accordance with various embodiments.

FIG. 12 is a side, cross-sectional view of another example microelectronic assembly having a via-trace-via structure, in accordance with various embodiments.

FIG. 13 is a side, cross-sectional view of another example microelectronic assembly having a via-trace-via structure, in accordance with various embodiments.

FIGS. 14A-14E are side, cross-sectional views of various stages in an example process for manufacturing a microelectronic assembly of FIG. 13, in accordance with various embodiments.

FIG. 15 is a side, cross-sectional view of another example microelectronic assembly having a via-trace-via structure, in accordance with various embodiments.

FIG. 16A is a schematic diagram of an input block and interconnect areas of an example microelectronic assembly having a via-trace-via structure, in accordance with various embodiments.

FIG. 16B is a side, cross-sectional schematic of the microelectronic assembly of FIG. 16A, in accordance with various embodiments.

FIG. 17A is a schematic diagram of an input/output block and interconnect areas of an example microelectronic assembly having a via-trace-via structure, in accordance with various embodiments.

FIG. 17B is a side, cross-sectional schematic of the microelectronic assembly of FIG. 17A along the A-A′ line, in accordance with various embodiments.

FIG. 17C is a side, cross-sectional schematic of the microelectronic assembly of FIG. 17A along the B-B′ line, in accordance with various embodiments.

FIG. 18A is a perspective view of an assembly including a via-trace-via structure, in accordance with various embodiments.

FIG. 18B is a cross-sectional view of the assembly of FIG. 18A along the A-A′ line, in accordance with various embodiments.

FIG. 18C is a cross-sectional view of the assembly of FIG. 18A along the B-B′ line, in accordance with various embodiments.

FIG. 19A is a perspective view of an assembly including a via-trace-via structure, in accordance with various embodiments.

FIG. 19B is a cross-sectional view of the assembly of FIG. 19A along the A-A′ line, in accordance with various embodiments.

FIG. 19C is a cross-sectional view of the assembly of FIG. 19A along the B-B′ line, in accordance with various embodiments.

FIG. 20 is a block diagram of an example electrical device that may include a microelectronic assembly having a via-trace-via structure, in accordance with any of the embodiments disclosed herein.

### DETAILED DESCRIPTION

Disclosed herein are via-trace-via structures with improved alignment, and related package substrates, packages, and computing device. For example, in some embodiments, an integrated circuit (IC) package substrate may include a conductive trace having a first surface and an opposing second surface; a first conductive via in a first dielectric layer, wherein the first conductive via is in contact with the first surface of the conductive trace; and a second conductive via in a second dielectric layer, wherein the second conductive via is in contact with the second surface of the conductive trace, wherein the second dielectric layer is on the first dielectric layer, and wherein the first conductive via, the second conductive via, and the conductive trace have a same width between 0.5 um and 25 um.

Communicating large numbers of signals in an integrated circuit (IC) package is challenging due to the increasingly small size of IC dies, thermal constraints, z-height constraints, form factor constraints, performance constraints, and power delivery constraints, among others. One of the main drivers for package design rules is the input/output (IO) density of traces per mm per conductive layer (IO/mm/layer). This becomes even more challenging as IO densities increase, and the size of conductive pathways decrease. Generally, the substrate of a package comprises a plurality of metal layers separated by dielectric layers. Conductive vias are used to provide electrical connections between the metal layers. Conventional package substrate manufacturing techniques have been limited in their ability to decrease feature size while retaining necessary accuracy and without requiring costly materials. For example, lithographically patterned vias formed using existing package substrate lithography tools and readily commercially available materials (e.g., commercially available dry film resists) have been constrained to have a diameter greater than 10 microns. Further, lithographic techniques that involve multiple masks or drilling layouts to pattern different features are subject to limitations on how accurately these different masks or drilling layouts can be aligned or overlaid with each other, and thus feature sizes have been required to be large enough to accommodate these alignment errors.

Methods and apparatuses to provide via-trace-via structures through two layers (e.g., a via-trace-via structure includes a stacked structure having a first via, a trace on the first via, and a second via on the trace) are described herein. Embodiments of via-trace-via structures as described herein advantageously reduce the via-trace-via sizes in substrate layers, thereby increasing the attainable line density in routing layers of a microelectronic package. Further, embodiments that use a simultaneous patterning technique with selective plating are described. For example, by using a dual-tone photoresist, the via-trace-via registration is advantageously defined by the alignment of two layers on a photomask. The photomask is rigid, substantially planar, and may be made using methods that are more precise than conventional registration methods, so that the trace and top via structures of the via-trace-via structure are approximately the same size as the bottom via. Reducing the sizes advantageously increases the density of the metal lines and other components on the substrate. For example, in the context of escape routing for high-bandwidth IO connections, reducing the sizes increases the maximum realizable density of IO connections. In some embodiments, an IO density may be between 20 IO/mm/layer and 1000 IO/mm/layer. In some embodiments, an IO density may be between 250 IO/mm/layer and 750 IO/mm/layer. In some embodiments, an IO density may be between 500 IO/mm/layer and 800 IO/mm/layer.

The structures and techniques disclosed herein enable the formation of smaller and better-aligned features (e.g., vias and traces) in package substrates and other IC components. Some of these embodiments may utilize standard package substrate lithography tools and commercially available materials, while achieving these benefits. Further, various ones of the manufacturing processes disclosed herein may be less expensive and/or less complex than conventional techniques, while also achieving improved results.

In the following detailed description, reference is made to the accompanying drawings that form a part hereof wherein like numerals designate like parts throughout, and in which is shown, by way of illustration, embodiments that may be practiced. It is to be understood that other embodiments may be utilized, and structural or logical changes may be made, without departing from the scope of the present disclosure. Therefore, the following detailed description is not to be taken in a limiting sense.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The drawings are not necessarily to scale. Although many of the drawings illustrate rectilinear structures with flat walls and right-angle corners, this is simply for ease of illustration, and actual devices made using these techniques will exhibit rounded corners, surface roughness, and other features.

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. As used herein, a “package” and an “IC package” are synonymous, as are a “die” and an “IC die.” The terms “top” and “bottom” may be used herein to explain various features of the drawings, but these terms are simply for ease of discussion, and do not imply a desired or required orientation. As used herein, the term “insulating” may mean “electrically insulating,” unless otherwise specified.

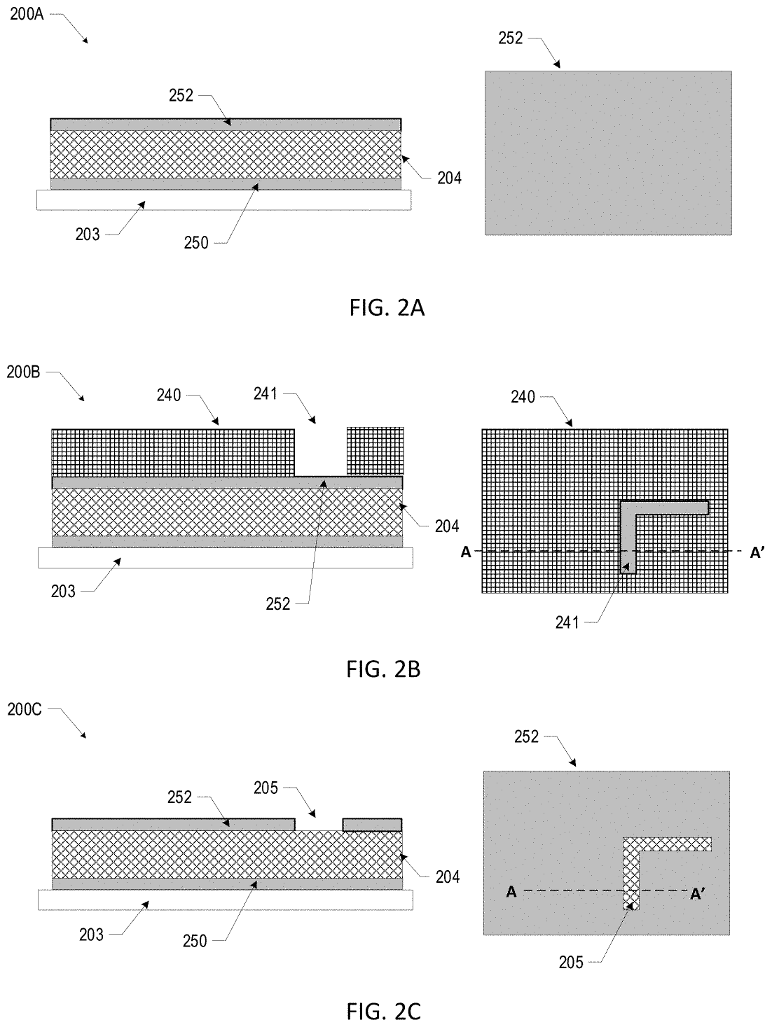

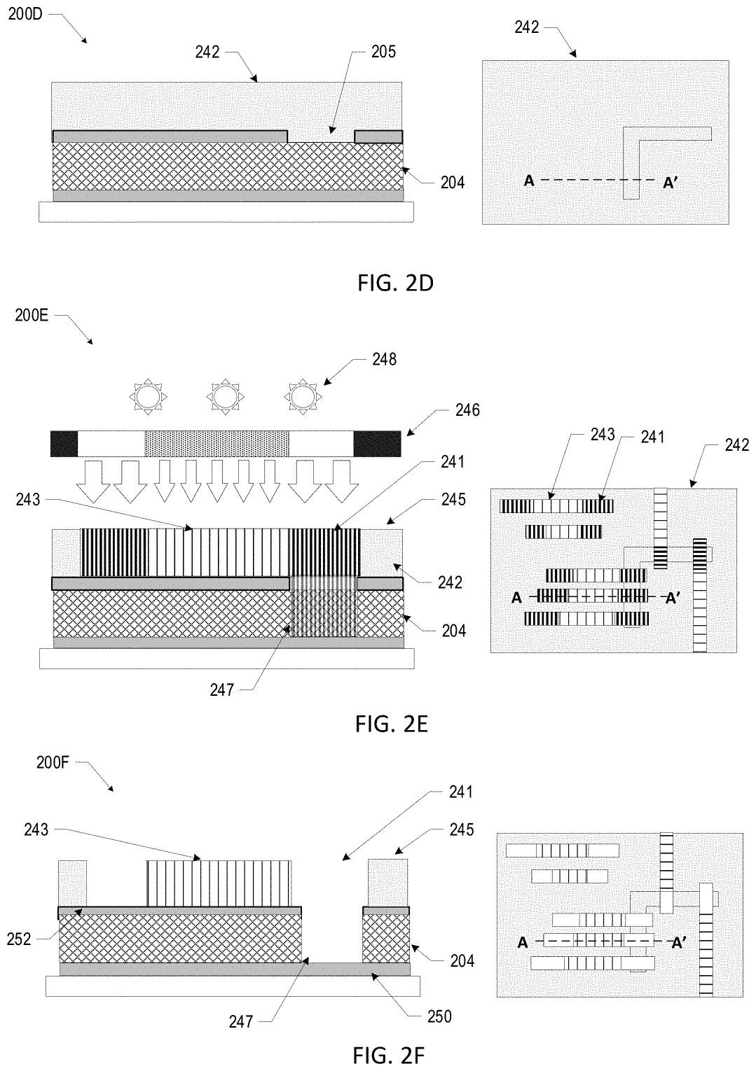

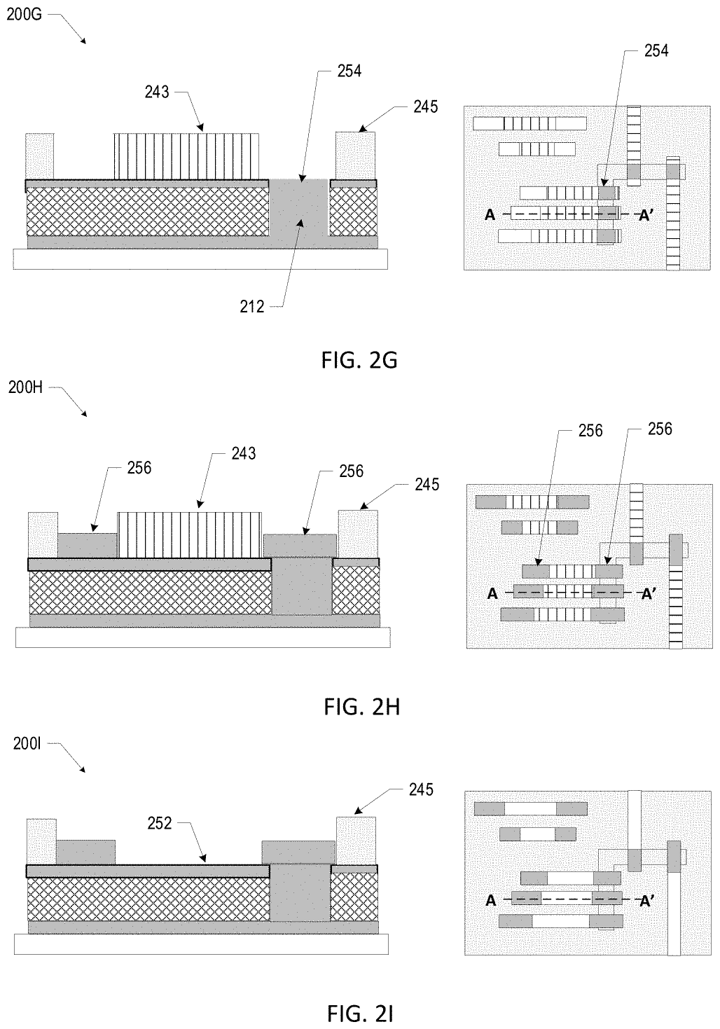

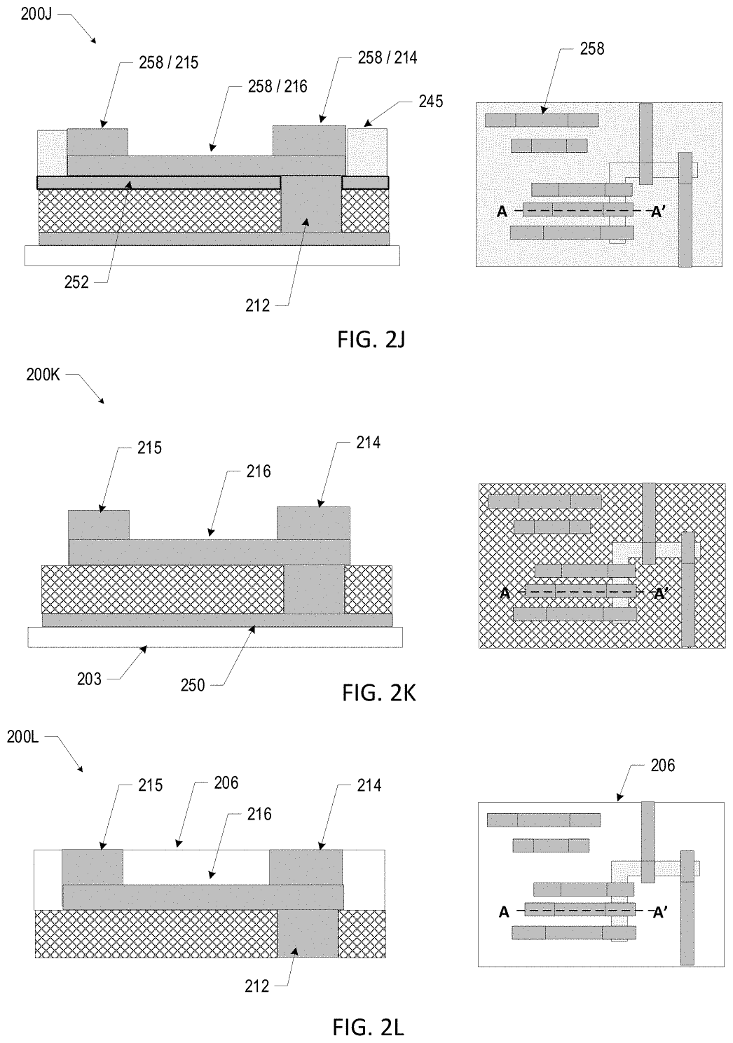

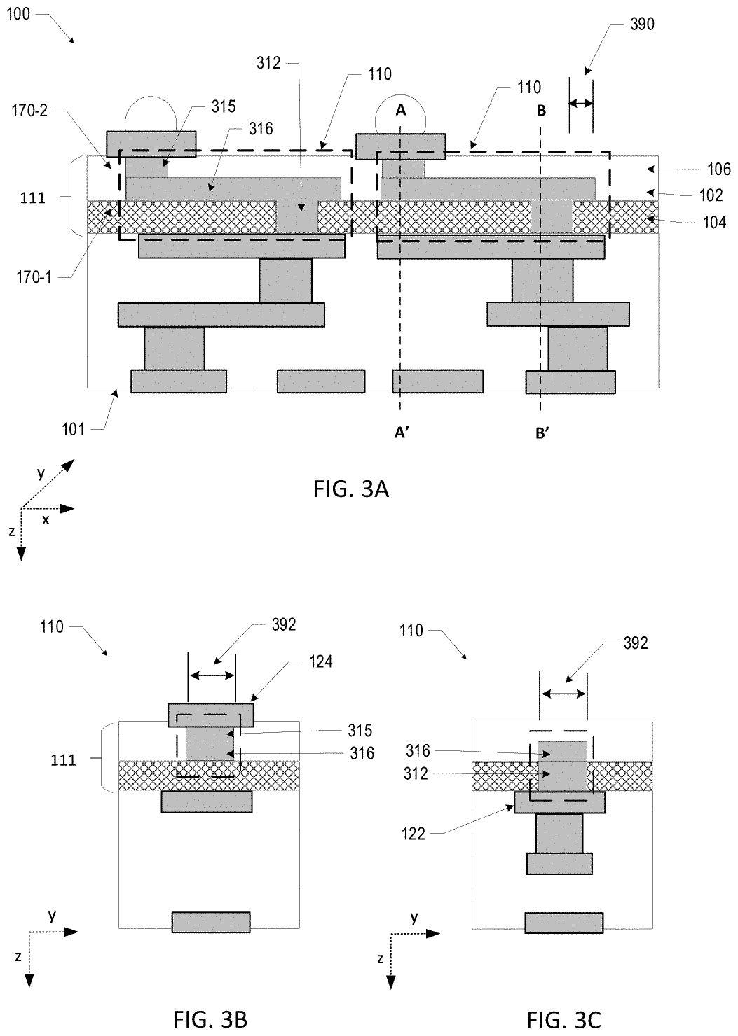

When used to describe a range of dimensions, the phrase “between X and V” represents a range that includes X and Y. For convenience, the phrase “FIG. 2” may be used to refer to the collection of drawings of FIGS. 2A-2L, the phrase “FIG. 3” may be used to refer to the collection of drawings of FIGS. 3A-3C, etc. Although certain elements may be referred to in the singular herein, such elements may include multiple sub-elements. For example, “an insulating material” may include one or more insulating materials.

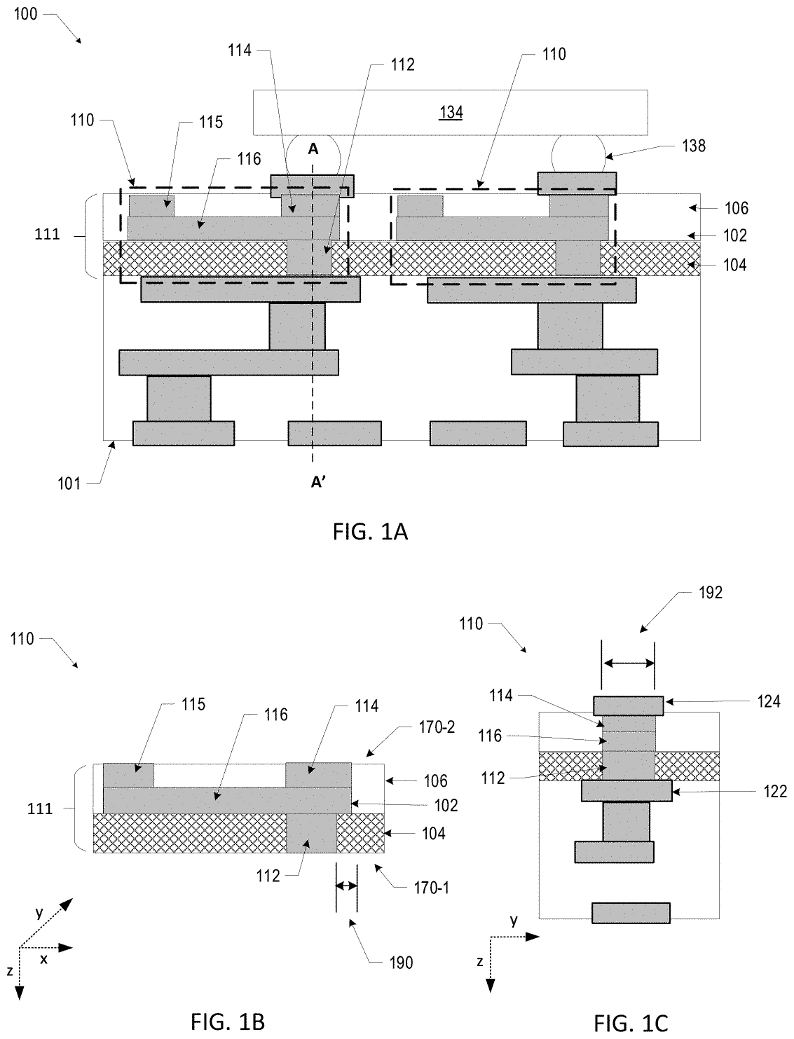

FIG. 1A is a cross-sectional view of a portion of an example microelectronic assembly 100, in accordance with various embodiments. The microelectronic assembly 100 may include a substrate 101 having a two-layer assembly 111 with one or more via-trace-via structures 110. The via-trace-via structure 110 may include a first via 112 in a first dielectric layer 104, a second via 114 in a second dielectric layer 106, and a trace 116 between the first via 112 and the second via 114 (i.e., a conductive layer 102 including the trace 116 between the first dielectric layer 104 and the second dielectric layer 106). A first via 112 may also be referred to herein as a bottom via. A trace 116 may also be referred to herein as a line or a transmission line. A second via 114 may also be referred to herein as a top via. In some embodiments, a first via 112 may be vertically aligned with a second via 114. As used herein, the term “vertically aligned” refers to being stacked or lined up one above the other. The microelectronic assembly 100 may further include a die 134 coupled to the substrate 101 by first-level interconnects (FLI) 138. The trace 116 may carry signals between the die 134 and the substrate 101, or may connect to a power plane or a ground plane.

As shown in FIG. 1B, which is a magnified view of the via-trace-via structure 110 of FIG. 1A, a via-trace-via structure 110 may include a bottom via 112 coupled to a first surface 170-1 of a trace 116, a top via 114 coupled to an opposing second surface 170-2 of the trace 116, where the top via and bottom via are vertically aligned, and may further include a third via 115 (e.g., a second top via) coupled to the second surface 170-2 of the trace 116, where the third via 115 is not vertically aligned with the bottom via 112 (e.g., the third via 115 is not lined up above the first via 112). The trace 116 and the top via 114 may be aligned in that a center point of the top via 114 may be aligned with the centerline of the trace 116. As used herein, the term “first via” refers to a first bottom via (e.g., callout numbers 112, 212, 312, 412, 512, 612, and 812); the term “second via” refers to a top via that is vertically aligned with the first via (e.g., callout numbers 114, 214, 514, 614, and 814); and the term “third via” refers to a top via that is not vertically aligned with the first via (e.g., callout numbers 115, 215, 315, 415, and 815). As shown in FIG. 1B, the trace 116 and the second via 114 may extend beyond the first via 112 along a side surface by an extension distance 190 (e.g., an overhang length in the x-direction). In particular, the first via may have a first footprint (e.g., x-y area), and the second via may have a second footprint where the second footprint is greater than the first footprint along a single side (e.g., in one direction) by the extension distance 190. In some embodiments, the extension distance 190 may be between 0.1 micron (um) and 7.5 um (e.g., between 1 um and 6 um, between 0.5 um and 3 um, or between 2 um and 4 um). In some embodiments, the extension distance may be less than 3 um. In some embodiments, the extension distance 190 may depend on the registration accuracy of the manufacturing process and on the type of substrate used.

FIG. 1C is a side, cross-sectional view along the A-A′ line (e.g., along the y-direction) of the microelectronic assembly 100 of FIG. 1A, in accordance with various embodiments. FIG. 1C shows the via-trace-via structure, where the first via 112, the trace 116, and the second via 114 are vertically aligned, and where the first via 112, the trace 116, and the second via 114 have a same width 192 (e.g., a width in the y-direction) along a thickness (e.g., z-dimension or z-height). In some embodiments, the width 192 may be between 0.5 um and 25 um. A same width 192 along a thickness may allow for minimum line/space (L/S) distances to be maintained. For example, in some embodiments, the L/S may have minimum dimensions of 0.5/0.5 and maximum dimensions of 25/25 (e.g., a dimension of an inter-trace spacing, which is the space between a trace and an adjacent trace, may be between 0.5 um and 25 um). For example, a L/S of 0.5/0.5 may result in a IO density of 1000 traces/mm/layer, and a L/S of 25/25 may result in an IO density of 20 traces/mm/layer. In some embodiments, the L/S may be 10/10 (e.g., 50 traces/mm/layer). In some embodiments, the IO may be between 1.5/1.5 and 7/7 (e.g., 333 traces/mm/layer and 71 traces/mm/layer). In some embodiments, a thickness (e.g., z-dimension) of the trace 116 may be between 0.5 um and 35 um. In some embodiments, a thickness (e.g., z-dimension) of the first via 112 may be between 2 microns and 35 microns. In some embodiments, a thickness (e.g., z-dimension) of the second via 114 may be between 2 microns and 50 microns. As shown in FIG. 1C, the first via 112 may be coupled to a bottom pad 122 and the second via 114 may be coupled to a top pad 124, where the bottom pad 122 and the top pad 124 have a width that is greater than the width 192. As shown in FIG. 1, the trace 116 may have a same width as the first via 112 and the second via 114, may have an extension distance 190 in a first length direction, and may have a trace distance in a second length direction, which is opposite the first length direction.

Although FIG. 1A illustrates three via-trace-via structures 110, a microelectronic assembly 100 may have any suitable number of via-trace-via structures 110, including more or less than three. Further, although the via-trace-via structures 110 disclosed herein are depicted with precisely rectilinear contours, this representation is simply illustrative, and via-trace-via structures fabricated using real manufacturing techniques may exhibit deviations from this representation. For example, a via-trace-via structure may exhibit angled faces and/or curved contours, for example, the area where the top via connects to the trace may be curved or sloped rather than a right angle. This curvature may arise due to the non-uniformity of the fabrication processes used to manufacture the via-trace-via structure (e.g., in accordance with the process discussed below with reference to FIGS. 2, 4, and 6).

The via-trace-via structures 110 disclosed herein may include a conductive material (e.g., a metal, such as copper). In some embodiments, the via-trace-via structures 110 may include multiple different conductive materials. In some embodiments, the via-trace-via structures 110 may include or may be in contact with various liner materials (e.g., a diffusion liner to limit diffusion of the conductive material of the via-trace-via structures 110 into the surrounding first dielectric material 104, and/or an adhesion liner to improve mechanical coupling between the via-trace-via structures 110 and the surrounding first dielectric material 104).

The first dielectric layer 104 may be made of any suitable material, including a photo-imageable dielectric (PID). In some embodiments, a PID may be deposited by lamination and patterned by exposure to light. In some embodiments, the PID may be deposited by spray coating or spin coating. The second dielectric layer 106 may be made of any suitable material and may include a single layer or may include multiple layers. In some embodiments, the second dielectric layer 106 may be an insulating material of the package substrate, such as an organic dielectric material, a fire retardant grade 4 material (FR-4), bismaleimide triazine (BT) resin, polyimide materials, glass reinforced epoxy matrix materials, ceramic-doped materials, or low-k and ultra low-k dielectric (e.g., carbon-doped dielectrics, fluorine-doped dielectrics, porous dielectrics, and organic polymeric dielectrics).

The via-trace-via structures disclosed herein may be part of conductive pathways through a substrate 101. The substrate 101 may be any suitable substrate and may be made of any suitable material, including, for example, an inorganic, an organic, a ceramic, a glass, and a semiconductor substrate. In some embodiments, the semiconductor substrate may be a crystalline substrate formed using a bulk silicon or a silicon-on-insulator substructure. In some embodiments, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. In some embodiments, the substrate 101 may include metallization interconnect layers for ICs. In some embodiments, the substrate 101 may include electronic devices, for example, transistors, memories, capacitors, inductors, resistors, optoelectronic devices, switches, and any other active and passive electronic devices that are separated by an electrically insulating layer, for example, an interlayer dielectric, a trench insulation layer, or any other insulating layer. In some embodiments, the substrate 101 may include interconnects, for example, vias, configured to connect the metallization layers. In some embodiments, the substrate 101 is a package substrate that may include an insulating material (e.g., a dielectric material formed in multiple layers, as known in the art) and one or more conductive pathways through the dielectric material (e.g., including conductive traces and/or conductive vias, as shown). In some embodiments, the insulating material of the package substrate may be a dielectric material, such as an organic dielectric material, a fire retardant grade 4 material (FR-4), BT resin, polyimide materials, glass reinforced epoxy matrix materials, or low-k and ultra low-k dielectric (e.g., carbon-doped dielectrics, fluorine-doped dielectrics, porous dielectrics, and organic polymeric dielectrics). In some embodiments, the substrate 101 may include a liquid crystal polymer, benzocyclobutene (BCB), polyimide, epoxy, or any combination thereof. In some embodiments, the substrate 101 may include inorganic fillers, such as silica. In some embodiments, the substrate 101 may include silicon, III-V, or a combination of these materials. In some embodiments, the substrate 101 is a multi-chip package substrate. In some embodiments, the substrate 101 is a system-in-package (SiP) substrate. In some embodiments, the substrate 101 is an interposer substrate.

Although FIG. 1A depicts a single die 134, the microelectronic assembly 100 may have any suitable number of dies. In some embodiments, the die 134 may be an active or passive die that may include IO circuitry, high-bandwidth memory, or enhanced dynamic random access memory (EDRAM). For example, die 134 may include a processor (e.g., including transistors, arithmetic logic units, and other components) that may include a central processing unit (CPU), a graphics processing unit (GPU), or both. In some embodiments, microelectronic assemblies disclosed herein may include a plurality of dies coupled to the package substrate or coupled to another die in a package-on-package (PoP) configuration. In some embodiments, the microelectronic assembly 100 may serve as a SiP in which multiple dies having different functionality are included. In such embodiments, the microelectronic assembly may be referred to as an SiP.

FIG. 1A illustrates a number of elements that are omitted from subsequent drawings for ease of illustration, but may be included in any of the microelectronic assemblies disclosed herein. Examples of such elements include the die 134 and the FLI 138.

Any suitable techniques may be used to manufacture microelectronic assemblies having a via-trace-via structure disclosed herein. For example, FIGS. 2A-2L are side, cross-sectional views through the A-A′ section and associated top views of various stages in an example process for manufacturing the via-trace-via structure 110 of FIG. 1, in accordance with various embodiments. Although the operations discussed below with respect to FIGS. 2A-2L are illustrated in a particular order, these operations may be performed in any suitable order. Additionally, although particular assemblies are illustrated in FIGS. 2A-2L, the operations discussed below with reference to FIGS. 2A-2L may be used to form via-trace-via structures.

FIG. 2A illustrates an assembly 200A including a temporary carrier 203 subsequent to depositing a first seed layer 250 on the carrier 203, depositing a first dielectric layer 204 on the first seed layer 250, and depositing a second seed layer 252 on the first dielectric layer 204. The first dielectric layer 204 may include a PID material. The first and second seed layers 250, 252 may be any suitable conductive material, including copper or a bilayer of titanium and copper. The first and second seed layers 250, 252 may be formed by depositing conductive material using any suitable technique, including, for example, electroplating, sputtering, electroless plating, chemical vapor deposition (CVD), metalorganic chemical vapor deposition (MOCVD), or atomic layer deposition (ALD). The carrier 203 may be of any suitable material, such as stainless steel, glass, silicon, fiber-glass reinforced epoxy, polyethylene terephthalate (PET), among others, and may be attached to the subassembly using any suitable means that may allow for removal at the end of the process, for example, an adhesive or an ultraviolet (UV) active release film. The adhesive or UV release film may be deposited using any suitable process, including lamination, slit coating, spin coating, or spray coating, among others.

FIG. 2B illustrates an assembly 200B subsequent to forming a first photoresist 240 over the second seed layer 252 and patterning the first photoresist 240 to provide openings. The first photoresist 240 may be deposited using any suitable technique, including lamination, slit coating, spin coating, or spray coating, among others. In some embodiments, the first photoresist 240 may be patterned using lithographic processes (e.g., exposed with a radiation source through a mask (not shown) and developed with a developer). The first photoresist 240 may be patterned to have any desired shape (e.g., L-shaped opening) and any number of shapes. After the first photoresist 240 has been patterned, the exposed portions of the second seed layer 252 may be removed, for example, by using a seed etching process. The exposed portions of the second seed layer 252 may have any suitable size and shape.

FIG. 2C illustrates assembly 200C subsequent to stripping the first photoresist 240, and removing the portions of the second seed layer 252 to expose one or more portions 205 of the first dielectric layer 204 (e.g., an L-shaped portion 205).

FIG. 2D illustrates assembly 200D subsequent to forming a second photoresist 242 over the second seed layer 252 and the portions 205 of the first dielectric layer 204. The second photoresist 242 may include any suitable material, including spin-on, spray on, slit coated, or dry film photoresist.

FIG. 2E illustrates assembly 200E subsequent to performing a lithographic operation to assembly 200D and exposing the second photoresist 242 to electromagnetic energy 248. For example, a single grayscale mask 246 may be used to simultaneously expose different areas of the second photoresist 242 to different amounts (“doses”) of electromagnetic energy as well as the portion 205 of the first dielectric layer 204. In particular, a first exposure dose area 241 may be exposed to a first dose of electromagnetic energy, a second exposure dose area 243 may be exposed to a second dose of electromagnetic energy different from the first dose, and a third exposure dose area 245 may be exposed to a third dose of electromagnetic energy different from the first and second doses. The magnitude of the second dose may be between the magnitude of the first dose and the magnitude of the third dose, so that the first exposure dose area 241 is most readily removed during development, the second exposure dose area 243 is next most readily removed during development, and the third exposure dose area 245 is least readily removed during development. In some embodiments, the photoresist 242 may be a negative-type resist in which unexposed (or less exposed) areas of the photoresist 242 may be more readily removed during subsequent development; in some such embodiments, the first dose of electromagnetic energy may be an approximately zero dose (e.g., the grayscale mask may be “black” in the area corresponding to the first exposure dose area 241). In some embodiments, the photoresist 242 may be a positive-type resist in which more heavily exposed areas of the photoresist 242 may be more readily removed during subsequent development; in some such embodiments, the third dose of electromagnetic energy may be an approximately zero dose (e.g., the grayscale mask may be “black” in the area corresponding to the third exposure dose area 245). Using a single grayscale mask to pattern the photoresist 242 into the exposure dose areas 241/243/245 may ensure that these exposure dose areas are aligned with each other in a desired manner; such alignment may not be achievable using conventional techniques in which vias and traces are separately patterned (e.g., using multiple masks, one or more masks, and/or one or more via drilling layouts, etc.) and thus are limited in their ability to achieve “perfect” alignment with each other (and therefore exhibit significant alignment offsets). The second seed layer 252 may act as a hard mask for the first dielectric layer 204. In the areas where the second seed layer was removed (e.g., portion 205), the first dielectric layer 204 may be exposed to electromagnetic energy 248 (e.g., a first dose) and the first dielectric exposure dose area 247 may be removed during development.

FIG. 2F illustrates an assembly 200F subsequent to developing the exposed photoresist of the assembly 200E so as to remove the first exposure dose area 241 and a first dielectric exposure dose area 247. In some embodiments, this development operation may be a “fast” develop so that only the first exposure dose area 241 and the first dielectric exposure dose area 247 (the most readily removed) are removed, and the second exposure dose area 243 and the third exposure dose area 245 remain in the assembly 200F. The removal of the first exposure dose area 241 may uncover a first portion of the second seed layer 252 and the removal of the first dielectric exposure dose area 247 may uncover a portion of the first seed layer 250.

FIG. 2G illustrates an assembly 200G subsequent to depositing a first conductive material 254 in an opening formed by removal of the first dielectric exposure dose area 247. In some embodiments, the first conductive material 254 may form a first via 212. The first conductive material 254 may be deposited to a desired thickness using any suitable technique. In some embodiments, the first conductive material 254 may be deposited by a plating operation (e.g., electroless plating).

FIG. 2H illustrates an assembly 200H subsequent to depositing a second conductive material 256 in an opening formed by removal of the first exposure dose area 241. The second conductive material 256 may be deposited to a desired thickness using any suitable technique. In some embodiments, the second conductive material 256 may be deposited by a plating operation (e.g., electroless plating).

FIG. 2I illustrates an assembly 2001 subsequent to developing the exposed photoresist of the assembly 200H so as to remove the second exposure dose area 243, and the third exposure dose area 245 remains in the assembly 2001. The removal of the second exposure dose area 243 may uncover a second portion of the second seed layer 252.

FIG. 2J illustrates an assembly 200J subsequent to depositing a third conductive material 258 in the openings formed by removal of the first and second exposure dose areas 241, 243 to form a second via 214, a trace 216, and a third via 215. The third conductive material 258 may be deposited to a desired thickness using any suitable technique. In some embodiments, the third conductive material 258 may be deposited by a plating operation (e.g., electroless plating).

FIG. 2K illustrates an assembly 200K subsequent to developing the exposed photoresist of the assembly 2001 so as to remove the third exposure dose area 245 to uncover a third portion of the second seed layer 252 and removing the exposed third portion of the second seed layer 252. In some embodiments, the exposed third portions of the second seed layer 252 may be removed with a seed etching process.

FIG. 2L illustrates an assembly 200L subsequent to depositing a second dielectric layer 206 over the first dielectric layer 204, the second via 214, the trace 216, and the third via 215, removing the carrier 203, and removing the first seed layer 250. In some embodiments, the first seed layer 250 may be removed with a seed etching process. The second dielectric layer 206 may be formed using any suitable process, such as lamination or slit coating and curing. In some embodiments, the second dielectric layer 206 may be formed to a thickness that is greater than a thickness of the second via 214 and a thickness of the third via 215 to ensure uniformity of the layer and cover the top surfaces of the second and third vias 214, 215. A controlled etch process may be used to remove dielectric material to expose the top surfaces of the second and third vias 214, 215. In some embodiments, the dielectric removal process may include a wet etch, a dry etch (e.g., a plasma etch), a wet blast, or a laser ablation (e.g., by using excimer laser). In some embodiments, the thickness of the second dielectric layer 206 may be minimized to reduce the etching time required to expose the top surfaces of the second and third vias 214, 215. In some embodiments, the thickness of the second dielectric layer 206 may be controlled such that the top surfaces of the second and third vias 214, 215 may extend above the top surface of the second dielectric layer 206 and the dielectric removal process may be omitted. The assembly 200L may be attached to another component using any suitable technique, such as lamination, adhesive, solder, or hybrid bonding, among others. In some embodiments, the carrier 203 may be used to transfer the assembly 200L and may be removed prior to attaching the assembly 200L to another component. In some embodiments, the second dielectric layer 206 may be attached to a second temporary carrier (not shown) prior to removing the carrier 203, and attached to another component using the second temporary carrier for transferring the assembly 200L. The finished assembly 200L may be a single unit or may be a repeating unit that may undergo a singulation process in which each unit is separated from one another to create a single two-layer assembly having via-trace-via structures.

FIG. 3A is a cross-sectional view of a portion of an example microelectronic assembly 100, in accordance with various embodiments. The microelectronic assembly 100 may include a substrate 101 having a two-layer assembly 111 with one or more via-trace-via structures 110. The via-trace-via structure 110 may include a first via 312 in a first dielectric layer 104, a third via 315 in a second dielectric layer 106, and a trace 316 between the first via 312 and the third via 315 (i.e., a conductive layer 102 including the trace 316 between the first dielectric layer 104 and the second dielectric layer 106). As shown in FIG. 3A, a via-trace-via structure 110 may include a first via 312 coupled to a first surface 170-1 of a trace 316, and a third via 315 coupled to an opposing second surface 170-2 of the trace 316, where the first via 312 and the third via 315 are not vertically aligned, and where a second via (e.g., a top via vertically aligned with the first via 312) is omitted. The trace 316 and the third via 315 may be aligned in that a center point of the third via 315 may be aligned with the centerline of the trace 316. The trace 316 may extend beyond the first via 312 along a side surface by an extension distance 390 (e.g., an overhang length in the x-direction). In some embodiments, the extension distance 390 may be between 0.1 um and 7.5 um, as described above with reference to extension distance 190 in FIG. 1. Although FIG. 3A illustrates two via-trace-via structures 110, a microelectronic assembly 100 may have any suitable number of via-trace-via structures 110, including more or less than two.

FIG. 3B is a side, cross-sectional view along the A-A′ line (e.g., along the y-direction) of the microelectronic assembly 100 of FIG. 3A, in accordance with various embodiments. FIG. 3B shows the via-trace-via structure 110, where the trace 316 and the third via 315 are vertically aligned, and where the trace 316 and the third via 315 have a same width 392 (e.g., a width in the y-direction) along a thickness (e.g., z-dimension). As shown in FIG. 3B, the third via 315 may be coupled to a top pad 124, and the top pad 124 may have a width that is greater than the width 392. In some embodiments, the third via 315 may be coupled to a power plane or a ground plane.

FIG. 3C is a side, cross-sectional view along the B-B′ line (e.g., along the y-direction) of the microelectronic assembly 100 of FIG. 3A, in accordance with various embodiments. FIG. 3C shows the via-trace-via structure, where the first via 312 and the trace 316 are vertically aligned, and where the first via 312 and the trace 316 have the same width 392 (e.g., a width in the y-direction) along a thickness (e.g., z-dimension). In some embodiments, the width 392 may have dimensions as described above with reference to width 192 in FIG. 1 (e.g., the width 192 may be between 0.5 um and 25 um). In some embodiments, a thickness (e.g., z-dimension) of the trace 316 may be between 0.5 microns and 35 microns. In some embodiments, a thickness (e.g., z-dimension) of the first via 312 may be between 2 microns and 35 microns. In some embodiments, a thickness (e.g., z-dimension) of the third via 315 may be between 2 microns and 50 microns. As shown in FIG. 3C, the first via 312 may be coupled to a bottom pad 122, and the bottom pad 122 may have a width that is greater than the width 392. In some embodiments, the first via 312 may be coupled to a power plane or a ground plane.

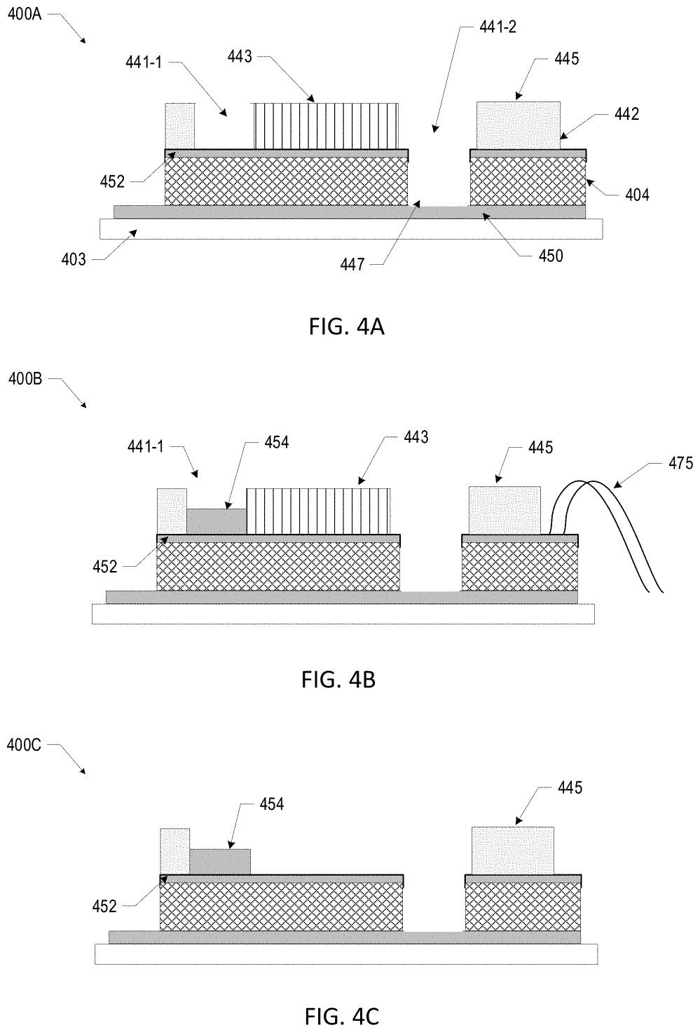

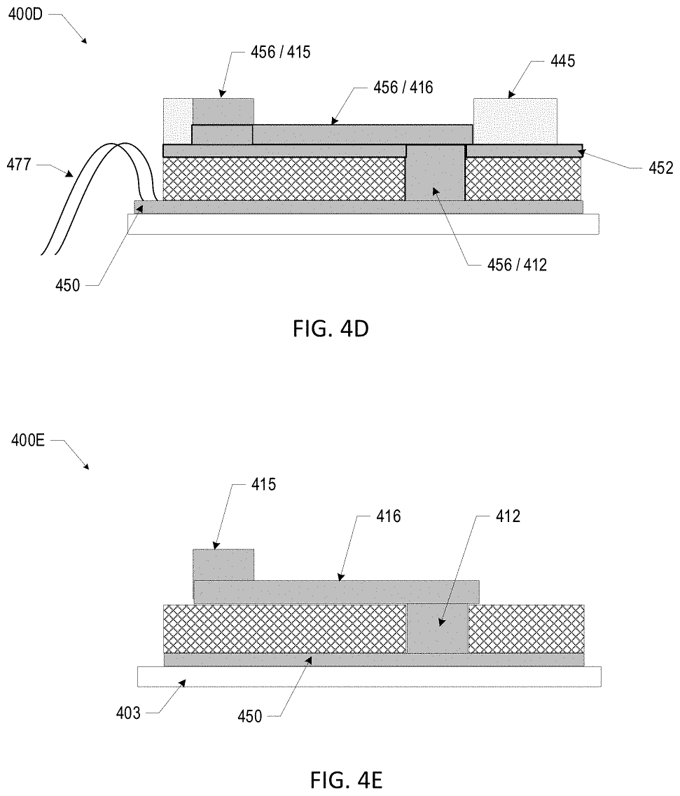

FIGS. 4A-4E are side, cross-sectional views of various stages in an example process for manufacturing the via-trace-via structure 110 of FIG. 3, in accordance with various embodiments.

FIG. 4A illustrates an assembly 400A including a temporary carrier 403, a first seed layer 450, a first dielectric layer 404, a second seed layer 452 having an etched portion formed using a first photoresist (not shown), and a second photoresist 442 subsequent to exposing the second photoresist 442 to a multiple dose levels of electromagnetic energy and performing a first development to remove the second photoresist 442 from first exposure dose areas 441 (e.g., 441-1, 441-2) and a first dielectric exposure dose area 447. As shown in FIG. 4A, the levels of electromagnetic energy may include the first dielectric exposure dose area 447, the first exposure dose area 441, a second exposure dose area 443, and a third exposure dose area 445. The first development forms openings in the first dielectric layer (e.g., exposure dose area 447) and in the second photoresist 442 (e.g., exposure dose areas 441-1 and 441-2). Assembly 400A may be manufactured as described above with reference to FIGS. 2A-2F.

FIG. 4B illustrates assembly 400B subsequent to depositing a first conductive material 454 in the exposure dose area 441-1. The first conductive material 454 may be selectively deposited in the exposure dose area 441-1 using an electroplating process by forming an electrical contact 475 with the second seed layer 452. The first conductive material 454 may be deposited to a desired thickness.

FIG. 4C illustrates an assembly 400C subsequent to developing the exposed photoresist of the assembly 400B so as to remove the second exposure dose area 443. The third exposure dose area 445 remains in the assembly 400C. The removal of the second exposure dose area 443 may uncover a portion of the second seed layer 452.

FIG. 4D illustrates an assembly 400D subsequent to depositing a second conductive material 456 in the first dielectric exposure dose area 447 and in the first and second exposure dose areas 441, 443 to form a first via 412, a trace 416, and a third via 415. The second conductive material 456 may be selectively deposited in the first dielectric exposure dose area 447 using an electroplating process by forming an electrical contact 477 with the first seed layer 450, then once the second conductive material 456 contacts the second seed layer 452, the second conductive material 456 may be deposited in the first and second exposure dose areas 441, 443. The second conductive material 456 may be deposited to a desired thickness. In another embodiment, the first seed layer 450 and the second seed layer 452 may have an electrical contact such that a first via and a portion of the second via may be formed simultaneously (not shown) by a first conductive material, and a trace may be formed subsequent to removing the second exposure dose area 443 and depositing a second conductive material in the first and second exposure dose areas 441, 443.

FIG. 4E illustrates an assembly 400E subsequent to developing the exposed photoresist of the assembly 400D so as to remove the third exposure dose area 445 to uncover a portion of the second seed layer 452 and removing the exposed portion of the second seed layer 452. In some embodiments, the exposed portion of the second seed layer 452 may be removed with a seed etching process. Additional processes may be performed, as described above with reference to FIGS. 2K-2L.

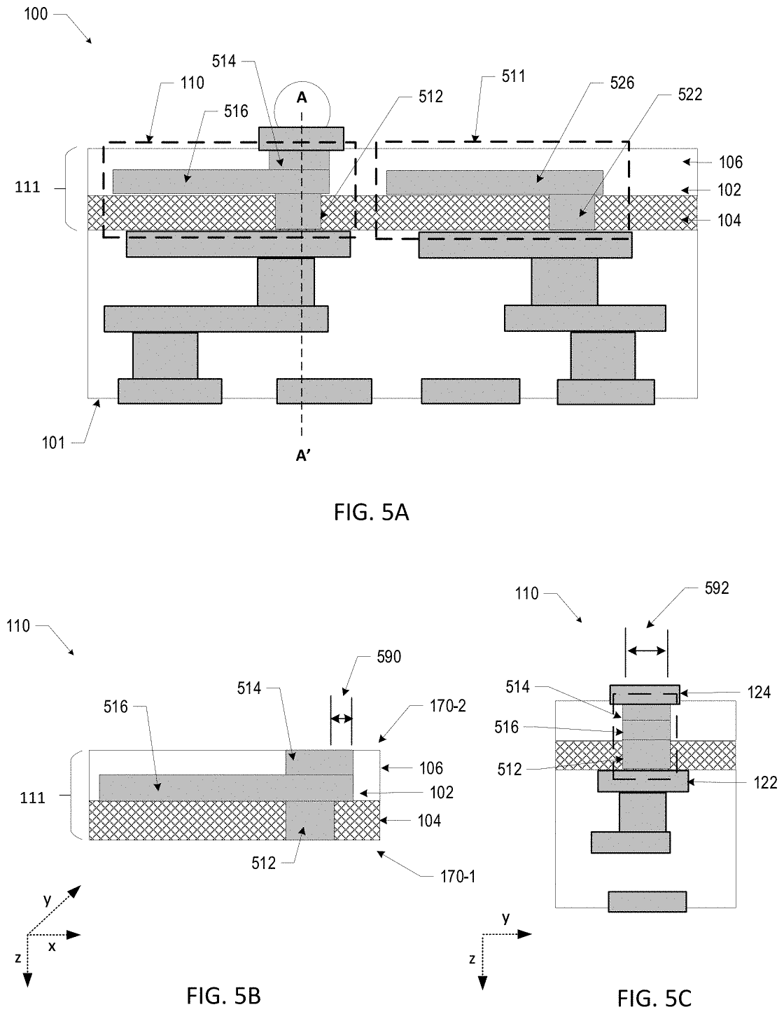

FIG. 5A is a cross-sectional view of a portion of an example microelectronic assembly 100, in accordance with various embodiments. The microelectronic assembly 100 may include a substrate 101 having a two-layer assembly 111 with one or more via-trace-via structures 110 and a via-trace structure 511. The via-trace-via structure 110 may include a first via 512 in a first dielectric layer 104, a second via 514 in a second dielectric layer 106, and a trace 516 between the first via 512 and the second via 514 (i.e., a conductive layer 102 including the trace 516 between the first dielectric layer 104 and the second dielectric layer 106). The via-trace structure 511 may include a bottom via 522 coupled to a trace 526.

As shown in FIG. 5B, a via-trace-via structure 110 may include a first via 512 coupled to a first surface 170-1 of the trace 516, and a second via 514 coupled to an opposing second surface 170-2 of the trace 516, where the first via 512 and the second via 514 are vertically aligned. The trace 516 and the second via 514 may be aligned in that a center point of the second via 514 may be aligned with the centerline of the trace 516. As shown in FIG. 5B, the trace 516 and the second via 514 may extend beyond the first via 512 along a side surface by an extension distance 590 (e.g., an overhang length in the x-direction). In some embodiments, the extension distance 590 may be between 0.1 um and 7.5 um, as described above with reference to extension distance 190 in FIG. 1. Although FIG. 5A illustrates one via-trace-via structure 110 and one via-trace structure 511, a microelectronic assembly 100 may have any suitable number of via-trace-via structures 110, including more than one, and any suitable number of via-trace structures 511.

FIG. 5C is a side, cross-sectional view along the A-A′ line (e.g., along the y-direction) of the microelectronic assembly 100 of FIG. 5A, in accordance with various embodiments. FIG. 5C shows the via-trace-via structure 110, where the first via 512, the trace 516, and the second via 514 are vertically aligned, and have a same width 592 (e.g., a width in the y-direction) along a thickness (e.g., z-dimension). The width 592 may have dimensions as described above with reference to width 192 in FIG. 1. As shown in FIG. 5C, the first via 512 may be coupled to a bottom pad 122 and the bottom pad 122 may have a width that is greater than the width 592. As shown in FIG. 5C, the second via 514 may be coupled to a top pad 124 and the top pad 124 may have a width that is greater than the width 592. In some embodiments, the first via 512 may be coupled to a power plane or a ground plane. In some embodiments, the second via 514 may be coupled to a power plane or a ground plane.

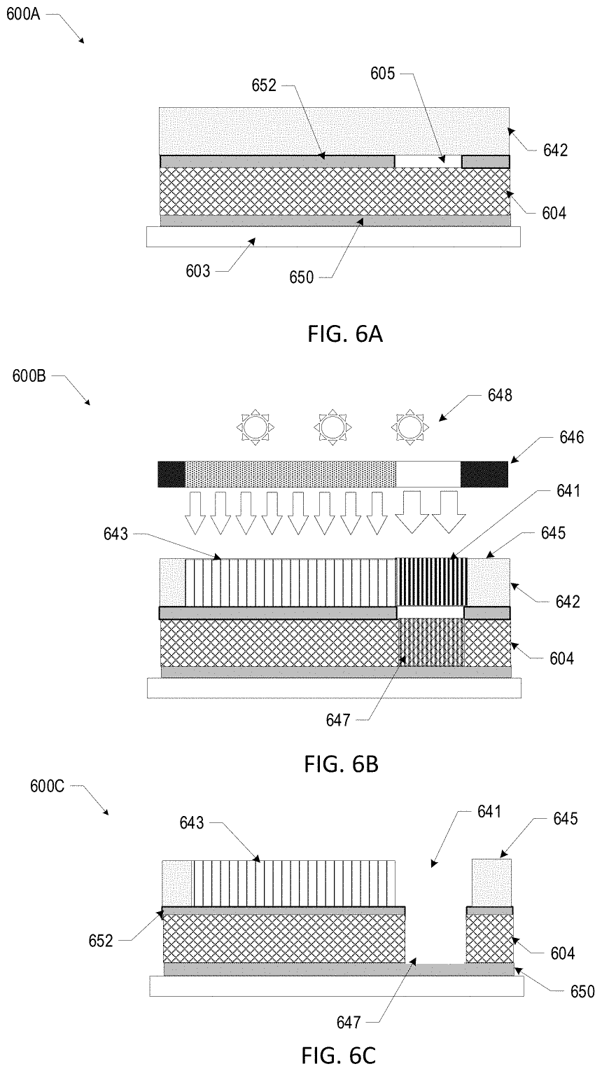

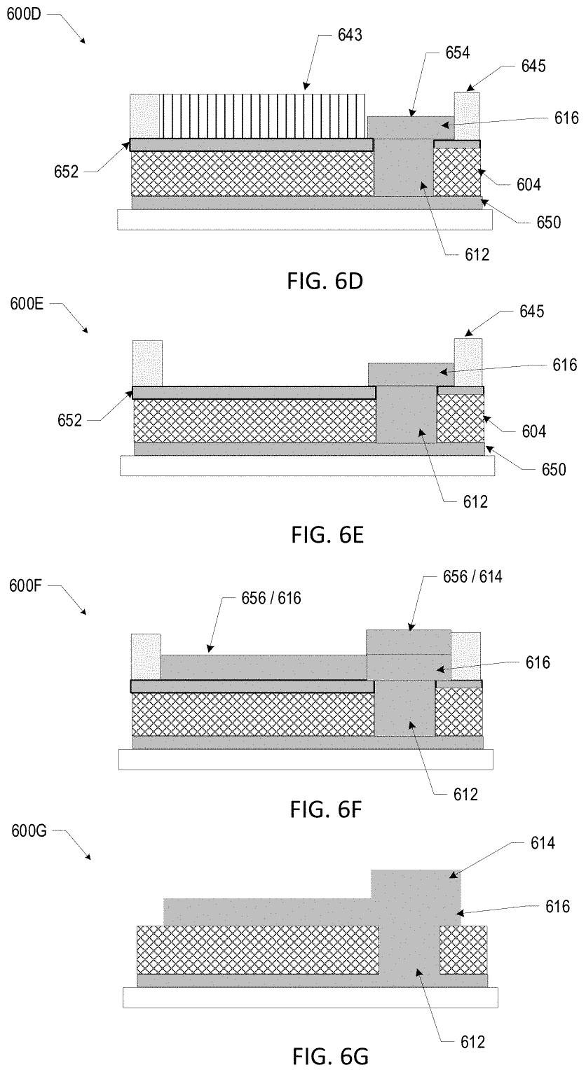

FIGS. 6A-6G are side, cross-sectional views of various stages in an example process for manufacturing the via-trace-via structure 110 of FIG. 5, in accordance with various embodiments.

FIG. 6A illustrates an assembly 600A including a temporary carrier 603, a first seed layer 650, a first dielectric layer 604, a second seed layer 652 having an etched portion 605 formed using a first photoresist (not shown), and a second photoresist 642. The assembly 600A may be manufactured as described above with reference to FIGS. 2A-2D. The etched portion 605 may have any suitable size and shape.

FIG. 6B illustrates assembly 600B subsequent to performing a lithographic operation to assembly 600A and exposing the second photoresist 642 as well as the first dielectric layer 604 to different doses of electromagnetic energy 648, as described above with reference to FIG. 2. In particular, a first exposure dose area 641 may be exposed to a first dose of electromagnetic energy, a second exposure dose area 643 may be exposed to a second dose of electromagnetic energy different from the first dose, and a third exposure dose area 645 may be exposed to a third dose of electromagnetic energy different from the first and second doses. The magnitude of the second dose may be between the magnitude of the first dose and the magnitude of the third dose, so that the first exposure dose area 641 is most readily removed during development, the second exposure dose area 643 is next most readily removed during development, and the third exposure dose area 645 is least readily removed during development. Using a single grayscale mask 646 to pattern the second photoresist 642 into the exposure dose areas 641/643/645 may ensure that these exposure dose areas are aligned with each other in a desired manner; such alignment may not be achievable using conventional techniques in which vias and traces are separately patterned (e.g., using multiple masks, one or more masks and/or one or more via drilling layouts, etc.) and thus are limited in their ability to achieve “perfect” alignment with each other (and therefore exhibit significant alignment offsets). The second seed layer 652 may act as a hard mask for the first dielectric layer 604. In the areas where the second seed layer was removed (e.g., portion 605), the first dielectric layer 604 may be exposed to electromagnetic energy 648 (e.g., a first dose) and the first dielectric exposure dose area 647 may be removed during development.

FIG. 6C illustrates an assembly 600C subsequent to developing the exposed photoresist of the assembly 600B so as to remove the first exposure dose area 641 and the first dielectric exposure dose area 647. In some embodiments, this development operation may be a “fast” development so that only the first exposure dose area 641 and the first dielectric exposure dose area 647 (the most readily removed) are removed, and the second exposure dose area 643 and the third exposure dose area 645 remain in the assembly 600C. The removal of the first exposure dose area 641 and the removal of the first dielectric exposure dose area 647 may uncover a portion of the first seed layer 650.

FIG. 6D illustrates an assembly 600D subsequent to depositing a first conductive material 654 in an opening formed by removal of the first dielectric exposure dose area 247 and the first exposure dose area 641. In some embodiments, the first conductive material 654 may form a first via 612 and a portion of a trace 616. The first conductive material 654 may be deposited to a desired thickness using any suitable technique. In some embodiments, the first conductive material 654 may be deposited by a plating operation (e.g., electroless plating). In some embodiments, the first conductive material 654 may be deposited by an electroplating operation.

FIG. 6E illustrates an assembly 600E subsequent to developing the exposed photoresist of the assembly 600D so as to remove the second exposure dose area 643, while the third exposure dose area 645 remains in the assembly 600E. The removal of the second exposure dose area 643 may uncover a portion of the second seed layer 652.

FIG. 6F illustrates an assembly 600F subsequent to depositing a second conductive material 656 in the openings formed by removal of the first and second exposure dose areas 641, 643 to form a second via 614 and the trace 616. The second conductive material 656 may be deposited to a desired thickness using any suitable technique. In some embodiments, the second conductive material 656 may be deposited by a plating operation (e.g., electroless plating). In some embodiments, the second conductive material 656 may be deposited by an electroplating operation.

FIG. 6G illustrates an assembly 600G subsequent to developing the exposed photoresist of the assembly 600F so as to remove the third exposure dose area 645 to uncover an other portion of the second seed layer 652 and removing the exposed portion of the second seed layer 652. In some embodiments, the exposed portion of the second seed layer 652 may be removed with a seed etching process. Additional processes may be performed, as described above with reference to FIGS. 2K-2L.

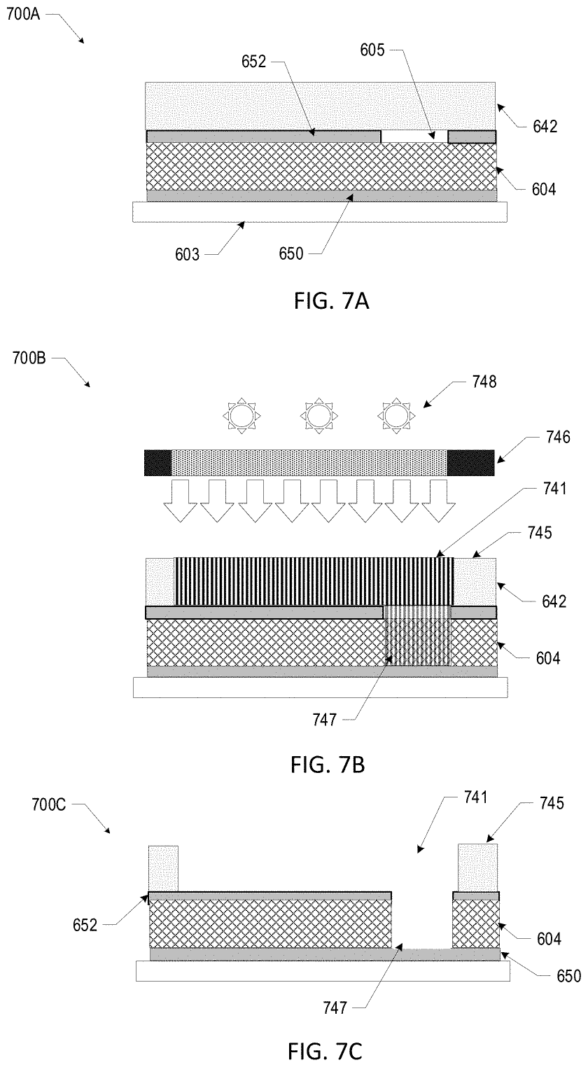

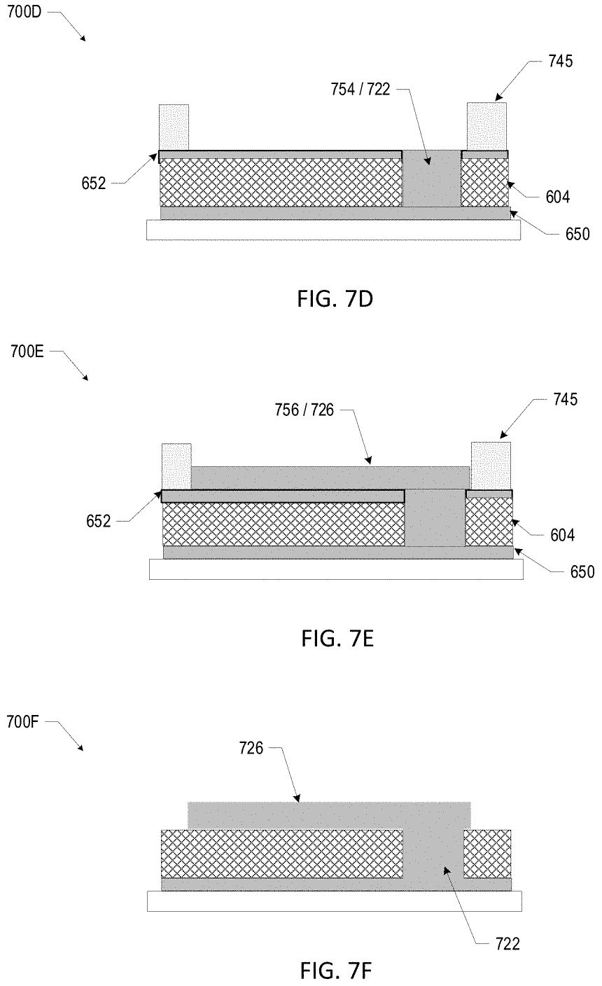

FIGS. 7A-7F are side, cross-sectional views of various stages in an example process for manufacturing the via-trace structure 511 of FIG. 5, in accordance with various embodiments. As shown in FIGS. 6 and 7, the via-trace structures 511 may be manufactured in combination with the via-trace-via structures 110.

FIG. 7A illustrates an assembly 700A including a temporary carrier 603, a first seed layer 650, a first dielectric layer 604, a second seed layer 652 having an etched portion 605 formed using a first photoresist (not shown), and a second photoresist 642. The assembly 700A may be manufactured as described above with reference to FIG. 6A. The etched portion 605 may have any suitable size and shape.

FIG. 7B illustrates assembly 700B subsequent to performing a lithographic operation to assembly 700A and exposing the second photoresist 642 as well as the first dielectric layer 604 to different doses of electromagnetic energy 748, as described above with reference to FIG. 2. In particular, a first exposure dose area 741 may be exposed to a first dose of electromagnetic energy, and a second exposure dose area 745 may be exposed to a second dose of electromagnetic energy different from the first dose. The magnitude of the first exposure dose area 741 may be most readily removed during development, and the second exposure dose area 745 is next most readily removed during development. Using a single grayscale mask 746 to pattern the second photoresist 642 into the exposure dose areas 741/745 may ensure that these exposure dose areas are aligned with each other in a desired manner; such alignment may not be achievable using conventional techniques in which vias and traces are separately patterned (e.g., using multiple masks, one or more masks and/or one or more via drilling layouts, etc.) and thus are limited in their ability to achieve “perfect” alignment with each other (and therefore exhibit significant alignment offsets). The second seed layer 652 may act as a hard mask for the first dielectric layer 604. In the areas where the second seed layer was removed (e.g., portion 605), the first dielectric layer 604 may be exposed to electromagnetic energy 748 (e.g., a first dose), and a first dielectric exposure dose area 747 may be removed during development.

FIG. 7C illustrates an assembly 700C subsequent to developing the exposed photoresist of the assembly 700B so as to remove the first exposure dose area 741 and the first dielectric exposure dose area 747. In some embodiments, this development operation may be a “fast” development so that only the first exposure dose area 741 and the first dielectric exposure dose area 747 (the most readily removed) are removed, and the second exposure dose area 745 may remain in the assembly 700C. The removal of the first exposure dose area 741 and the removal of the first dielectric exposure dose area 747 may uncover a portion of the first seed layer 650.

FIG. 7D illustrates an assembly 700D subsequent to depositing a first conductive material 754 in an opening formed by removal of the first dielectric exposure dose area 747. In some embodiments, the first conductive material 754 may form a first via 722. The first conductive material 754 may be deposited to a desired thickness using any suitable technique. In some embodiments, the first conductive material 754 may be deposited by a plating operation (e.g., electroless plating).

FIG. 7E illustrates an assembly 700E subsequent to depositing a second conductive material 756 in the openings formed by removal of the first exposure dose area 741 to form a trace 726. The second conductive material 756 may be deposited to a desired thickness using any suitable technique. In some embodiments, the second conductive material 756 may be deposited by a plating operation (e.g., electroless plating).

FIG. 7F illustrates an assembly 700F subsequent to developing the exposed photoresist of the assembly 700E so as to remove the second exposure dose area 745 to uncover an other portion of the second seed layer 652 and removing the exposed portion of the second seed layer 652. In some embodiments, the exposed portion of the second seed layer 652 may be removed with a seed etching process. Additional processes may be performed, as described above with reference to FIGS. 2K-2L.

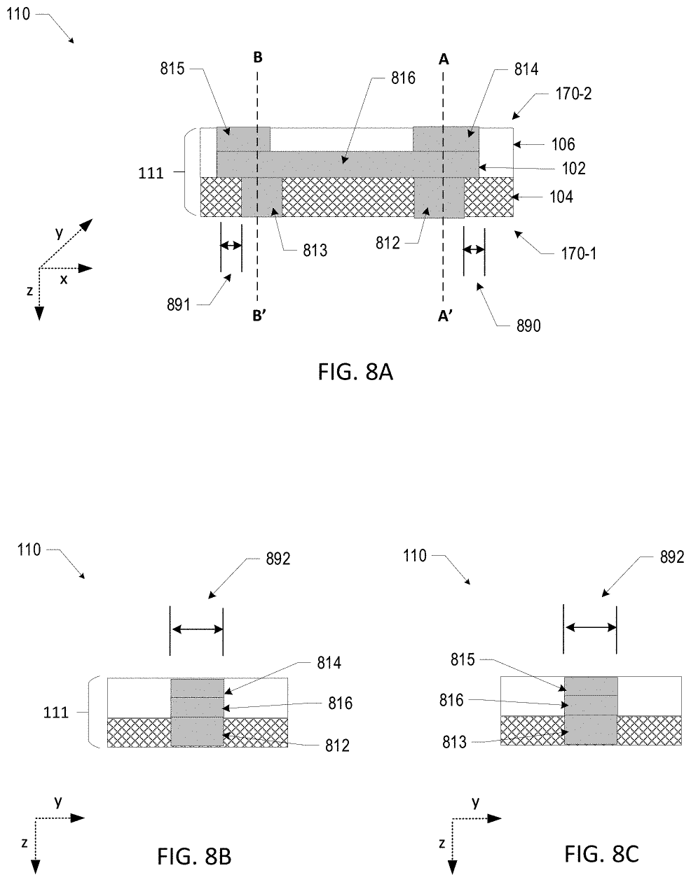

FIG. 8A is a cross-sectional view of a portion of another example via-trace-via structure 110 in a two-layer assembly 111. The via-trace-via structure 110 may include a first via 812 and a fourth via 813 in a first dielectric layer 104, a second via 814 and a third via 815 in a second dielectric layer 106, and a trace 816 between the first dielectric layer 104 and the second dielectric layer 106. As shown in FIG. 8A, a via-trace-via structure 110 may include the first via 812 and the fourth via 813 coupled to a first surface 170-1 of the trace 816, and the second via 814 and the third via 815 coupled to an opposing second surface 170-2 of the trace 816, where the first via 812 and the second via 814 are vertically aligned, and the third via 815 and the fourth via 813 are vertically aligned. The second via 814 and the trace 816 may extend beyond the first via 812 along a first side surface by an extension distance 890 (e.g., an overhang length in the x-direction). In some embodiments, the extension distance 890 may be between 0.1 um and 7.5 um, as described above with reference to extension distance 190 in FIG. 1. The third via 815 and the trace 816 may extend beyond the fourth via 813 along a second side surface by an extension distance 891 (e.g., an overhang length in the x-direction). In some embodiments, the extension distance 891 may be between 0.1 um and 7.5 um, as described above with reference to extension distance 190 in FIG. 1. In some embodiments, the extension distances 890 and 891 are the same. In some embodiments, the extension distances 890 and 891 are different. The trace-via-trace structure 110 of FIG. 8 may be manufactured as described above with reference to FIGS. 2, 4, and 6, in particular, by including an opening in the first dielectric layer 104 for forming the fourth via 813.

FIG. 8B is a side, cross-sectional view along the A-A′ line (e.g., along the y-direction) of the via-trace-via structure 110 of FIG. 8A, in accordance with various embodiments. FIG. 8B shows the via-trace-via structure 110, where the first via 812, the trace 816, and the second via 814 are vertically aligned and have a same width 892 (e.g., a width in the y-direction) along a thickness (e.g., z-dimension).

FIG. 8C is a side, cross-sectional view along the B-B′ line (e.g., along the y-direction) of the via-trace-via structure 110 of FIG. 8A, in accordance with various embodiments. FIG. 8C shows the via-trace-via structure 110, where the fourth via 813, the trace 816, and the third via 815 are vertically aligned and have a same width 892 (e.g., a width in the y-direction) along a thickness (e.g., z-dimension). In some embodiments, the width 892 may be as described above with reference to width 192 in FIG. 1.

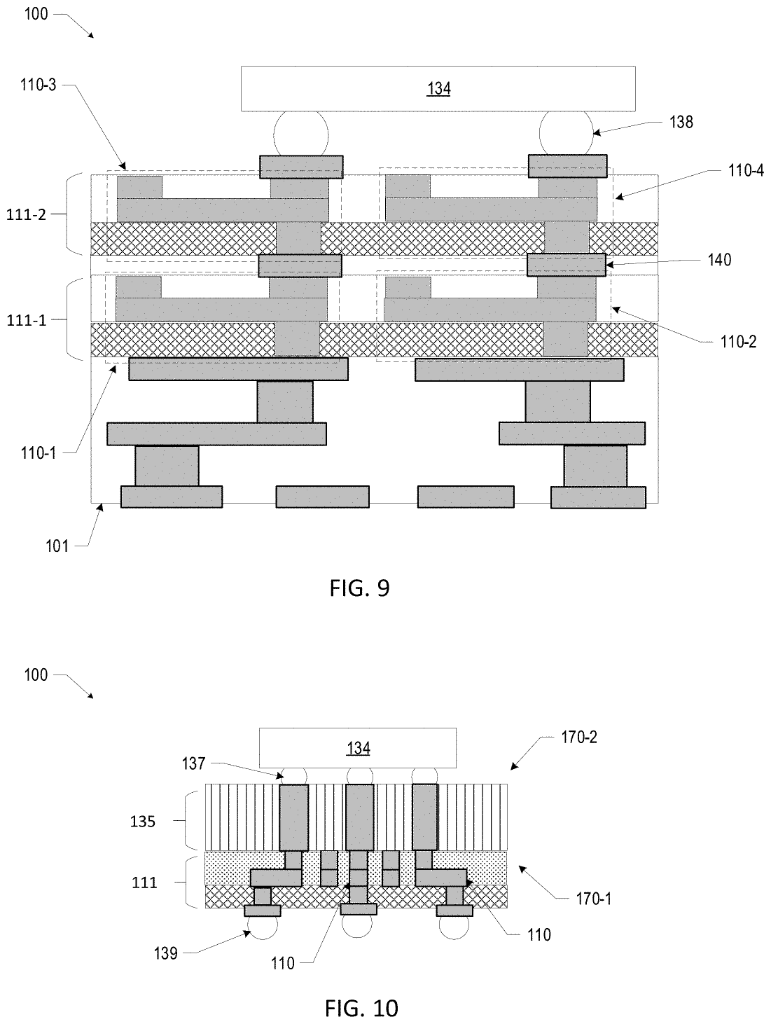

FIG. 9 is a cross-sectional view of a portion of an example microelectronic assembly 100, in accordance with various embodiments. The microelectronic assembly 100 may include via-trace-via structures 110 in multiple layers, where via-trace-via structures 110-1 and 110-2 are in a first two-layer assembly 111-1, and via-trace-via structures 110-3 and 110-4 are in a second two-layer assembly 111-2. The first two-layer assembly 111-1 may be coupled to the second two-layer assembly 111-2 by via-on-pad structures 140. The via-on-pad structures 140 may be formed by a standard lithographic process, a semi-additive process, or another known process for forming via-on-pad structures. Although FIG. 9 shows a particular number of two-layer assemblies 111 with the via-trace-via structures stacked vertically, a microelectronic assembly 100 may include any suitable number of via-trace-via two-layer assemblies 111 and the via-trace-via structures may have any suitable arrangement (e.g., the via-trace-via structures may not be stacked vertically). Further, the microelectronic assembly 100 may include any of the via-trace-via structures 110 disclosed herein.

FIG. 10 is a cross-sectional view of a portion of an example microelectronic assembly 100 having via-trace-via structures 110, in accordance with various embodiments. The microelectronic assembly 100 may include a die 134, an interposer 135, and a two-layer assembly 111 including via-trace-via structures 110. The interposer 135 may include a first surface 170-1 and an opposing second surface 170-2. The interposer 135 may be an active interposer or a passive interposer. The two-layer assembly 111 having via-trace-via structures 110 may be on the first surface 170-1 (e.g., on a backside) of the interposer 135, and the die 134 may be coupled on the second surface 170-2 by interconnects 137. In some embodiments, the interconnects 137 may be FLIs 138. The microelectronic assembly 100 may be coupled to other electronic components, such as a package substrate or a circuit board, by interconnects 139. The interconnects 137, 139 may include solder balls (as shown in FIG. 10), an adhesive, an underfill material, metal-to-metal interconnects, and/or any other suitable electrical and/or mechanical coupling structure. In some embodiments, the microelectronic assembly 100 may include a dual-damascene layer (not shown) on the second surface 170-2 of the interposer 135, and the die 134 may be coupled to the dual-damascene layer.

In some embodiments, the interposer 135 may be formed of an epoxy resin, a fiberglass-reinforced epoxy resin, an epoxy resin with inorganic fillers, a ceramic material, or a polymer material such as polyimide. In some embodiments, the interposer 135 may be formed of alternate rigid or flexible materials that may include the same materials described above for use in a semiconductor substrate, such as silicon, germanium, and other group III-V and group IV materials. The interposer 135 may include metal interconnects and vias (not shown), including but not limited to through-silicon vias (TSVs). The interposer 135 may further include embedded devices, including both passive and active devices. Such devices may include, but are not limited to, capacitors, decoupling capacitors, resistors, inductors (e.g., air-core inductors), fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 135.

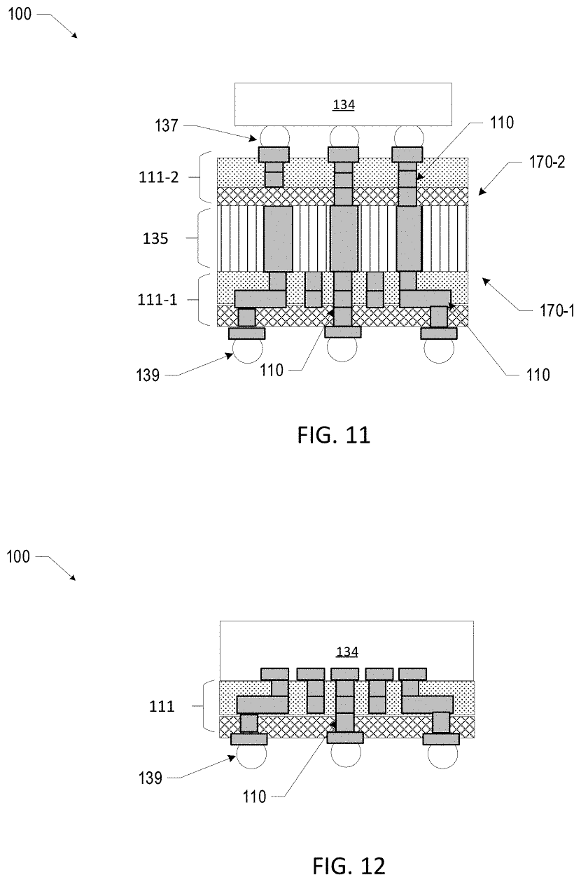

FIG. 11 is a cross-sectional view of a portion of an example microelectronic assembly 100 having via-trace-via structures 110, in accordance with various embodiments. The microelectronic assembly 100 may include a die 134, an interposer 135, and a first two-layer assembly 111-1 including via-trace-via structures 110, and a second two-layer assembly 111-2 having via-trace-via structures 110. The interposer 135 may include a first surface 170-1 and an opposing second surface 170-2. The first two-layer assembly 111-1 having via-trace-via structures 110 may be on the first surface 170-1 (e.g., on a backside) of the interposer 135, and the second two-layer assembly 111-2 may be on the second surface 170-2. The die 134 may be coupled to the second two-layer assembly 111-2 by interconnects 137. The microelectronic assembly 100 may be coupled to a package substrate or a circuit board by interconnects 139. In some embodiments, the microelectronic assembly 100 may include a dual-damascene layer (not shown) between the interposer 135 and the second two-layer assembly 111-2. In some embodiments, the first two-layer assembly 111-1 may be omitted.

FIG. 12 is a cross-sectional view of an example microelectronic assembly 100 having via-trace-via structures 110, in accordance with various embodiments. The microelectronic assembly 100 may include a die 134 having a two-layer assembly 111 including via-trace-via structures 110 on an active surface of the die 134. The die 134 may be coupled to an electrical component, such as a package substrate or a circuit board, via the interconnects 139. The two-layer assembly 111 including via-trace-via structures 110 may enable fan-in wafer level packaging, such as enabling chip-scale packages on wafers, having improved mechanical compatibility for circuit board attachment.

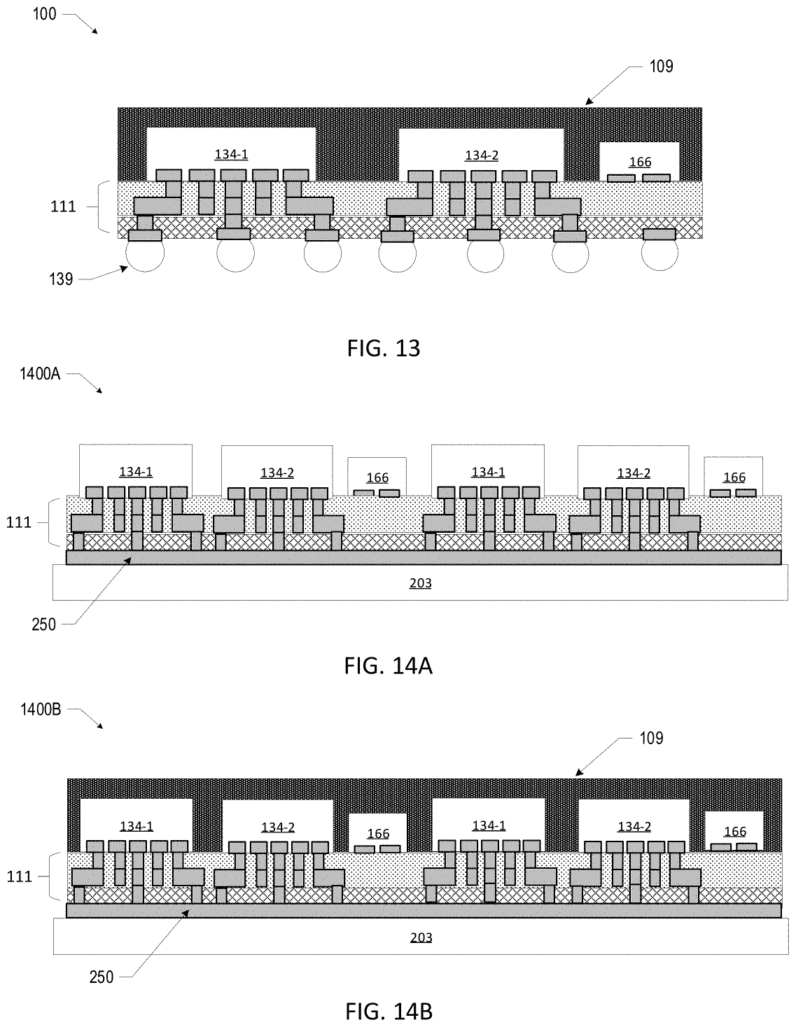

FIG. 13 is a cross-sectional view of a microelectronic assembly 100, in accordance with various embodiments. The microelectronic assembly 100 may include a two-layer assembly 111 having via-trace-via structures 110 coupled to one or more dies 134-1, 134-2, where the dies 134 are surrounded by a mold material 109. In some embodiments, the mold material may include epoxy, as suitable. In some embodiments, the microelectronic assembly 100 may further include an electronic component 166. In some embodiments, the electronic component 166 may be a passive component, such as a capacitor, or an inductor, among others. The two-layer assembly 111 having via-trace-via structures 110 may enable fan-out wafer level packaging (WLP) or panel level packaging (PLP).

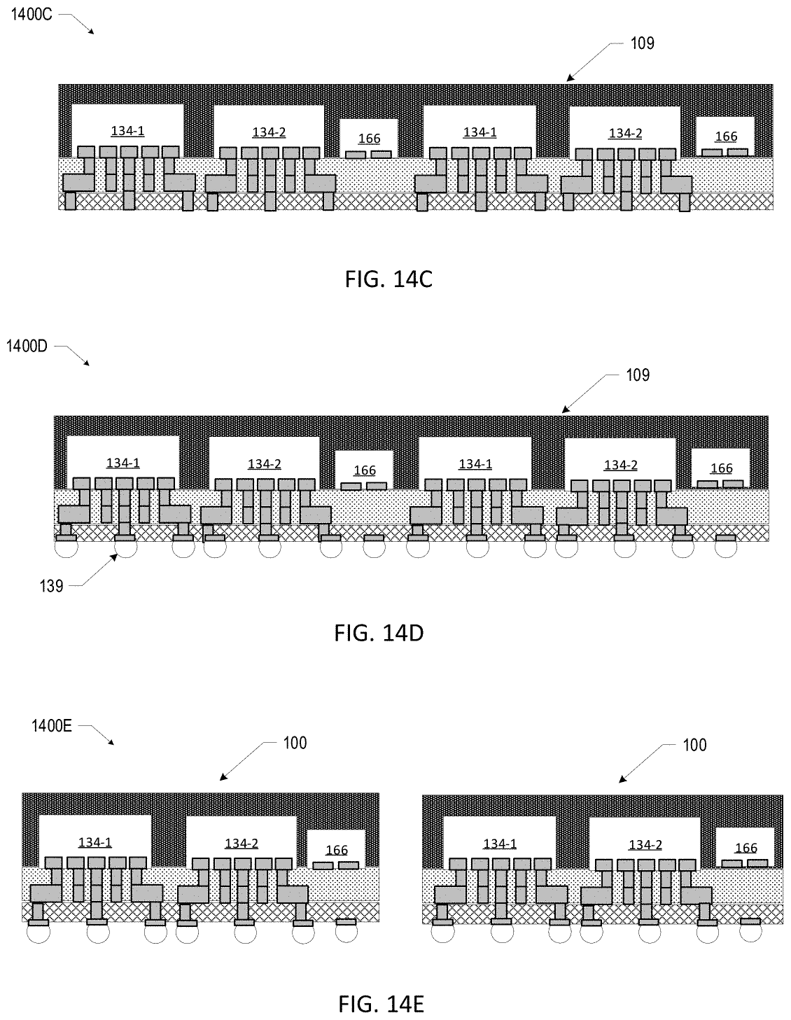

FIGS. 14A-14E are side, cross-sectional views of various stages in an example process for manufacturing the microelectronic assembly 100 of FIG. 13, in accordance with various embodiments.

FIG. 14A illustrates assembly 1400A subsequent to manufacturing a two-layer assembly 111 having via-trace-via structures 110 and attaching first dies 134-1, second dies 134-2, and electronic components 166 to the surface of the two-layer assembly 111. The two-layer assembly 111 may include a first seed layer 250 and a temporary carrier 203. The two-layer assembly 111 having via-trace-via structures 110 may be manufactured as described above with reference to FIGS. 2, 4, and 6.

FIG. 14B illustrates assembly 1400B subsequent to forming a mold material on the surface of the two-layer assembly 111 and over the dies 134 and electronic components 166.

FIG. 14C illustrates assembly 1400C subsequent to removing the carrier 203 and removing the first seed layer 250. The carrier 203 and the first seed layer 250 may be removed as described above with reference to FIG. 2.

FIG. 14D illustrates assembly 1400D subsequent to attaching interconnects 139. As shown in FIG. 14D, in some embodiments, the interconnects 139 may include solder balls.

FIG. 14E illustrates assembly 1400E subsequent to singulating the microelectronic assemblies 100. In some embodiments, the microelectronic assemblies 100 may be singulated prior to solder ball attachment. Further operations may be performed as suitable (e.g., attaching to a package substrate, attaching to a circuit board, etc.).

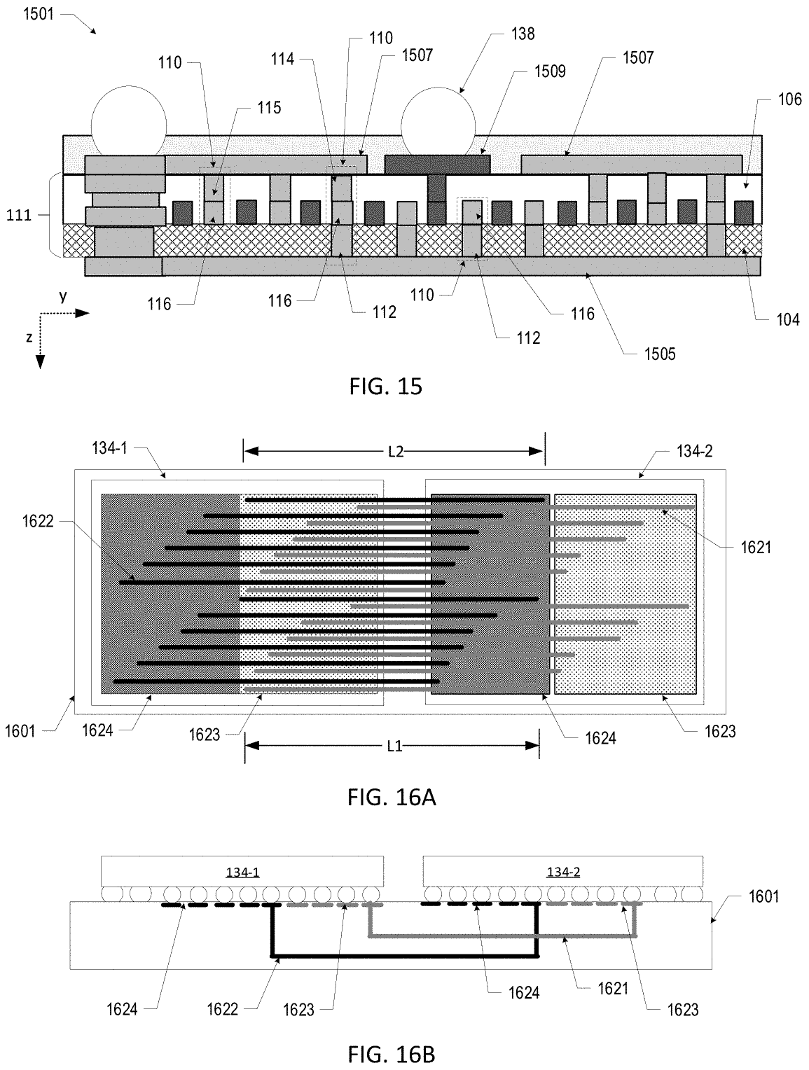

FIG. 15 is a cross-sectional view of a portion of an example package substrate 1501 having via-trace-via structures 110, in accordance with various embodiments. The package substrate 1501 may include a first ground plane 1505, a second ground plane 1507, and a two-layer assembly 111 having via-trace-via structures 110 between the first ground plane 1505 and the second ground plane 1507. The via-trace-via structures 110 show a cross-sectional view of a width of the via-trace-via structures. Various ones of the via-trace-via structures 110 may include a first via 112 in a first dielectric layer 104, a trace 116, and a second via 114 in a second dielectric layer 106 where the first via 112 and the second via 114 are vertically aligned. Various ones of the via-trace-via structures 110 may include a first via 112 in a first dielectric layer 104, a trace 116, and a third via 115 in a second dielectric layer 106 where the first via 112 and the third via 115 are not vertically aligned. As shown in FIG. 15, the package substrate 1501 may include via-trace-via structures that are coupled to a ground plane (as depicted in FIG. 15 as light gray pathways) alternating with via-trace-via structures that transmit signals (as depicted in FIG. 15 as dark gray pathways). The alternating ground and signal arrangement of the via-trace-via structures 110 may provide for improved ground shielding for high speed signals and may enable high ground-to-signal ratios (e.g., up to 1:1). The via-trace-via structure 110 may be coupled to the first ground plane 1505 by the first via 112, may be coupled to the second ground plane 1507 by the second via 114 or the third via 115, or may be coupled to the first ground plane 1505 and the second ground plane by the first via 112 and the second via 114, respectively. The via-trace-via structures that transmit signals may be coupled to a FLI 138 by a conductive pad 1509. The via-trace-via structures 110 may provide for coupling the third via 115 to the conductive pad 1509 and coupling the first via 112 to a conductive pad that connects to conductive pathways in a lower layer (not shown) (e.g., the layer below the two-layer assembly 111, for example, as described above with reference to FIG. 9) while maintaining maximal trace density for given design rules (e.g., minimum L/S distances).

FIG. 16A is a schematic diagram of an IO block and interconnect areas 1623, 1624 of two dies 134-1, 134-2 coupled to a package substrate 1601 having via-trace-via structures. The light gray lines depict first signal lines 1621 having interconnect areas 1623, and the black lines depict second signal lines 1622 having interconnect areas 1624. In some embodiments, as shown in FIG. 16A, a length L1 of the first signal lines 1621 and a length L2 of the second signal lines 1622 may be approximately equal. In some embodiments, the length L1 of the first signal lines and the length L2 of the second signal lines are different. The signal lines may have any suitable length. In some embodiments, individual signal lines (e.g., first signal lines 1621 or second signal lines 1622) may have different lengths (not shown). For example, one of a first signal line may have a length L3 and another of a first signal line may have a length L4, and the length L3 may be different from the length L4 (not shown). In some embodiments, one or more individual signal lines may have a same length L5 and one or more individual signal lines may have a same length L6, and the length L5 may be different from the length L6 (not shown). In some embodiments, the lengths of the signal lines may be approximately equal for different IO blocks. FIG. 16B is a cross-sectional view of the IO block and interconnect areas of FIG. 16A. As shown in FIG. 16B, the via-trace-via structures 110 disclosed herein may enable connectivity through one layer with minimal reduction to the IO density. In some embodiments, the via-trace-via structures may cause an IO block to grow laterally, such that associated timing discrepancies may arise between IO blocks, which may be minimized.

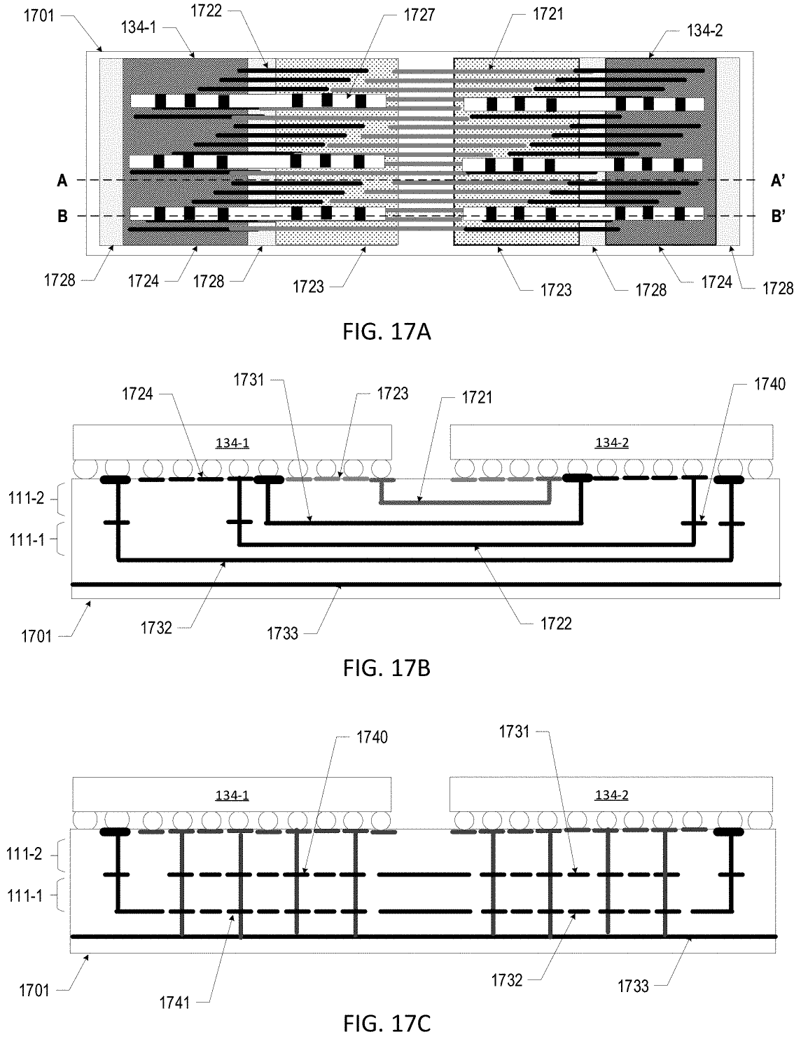

FIG. 17A is a schematic diagram of an IO block, and signal interconnect areas 1723, 1724 and power interconnect areas 1728 of two dies 134-1, 134-2 coupled to a package substrate 1701 having via-trace-via structures. The first signal lines 1721 may have signal interconnect areas 1723, the second signal lines 1722 may have signal interconnect areas 1724, and the power lines 1727 may have power interconnects areas 1728. FIG. 17B is a cross-sectional view of the IO block of FIG. 17A along the A-A′ line. The package substrate 1701 may include a first two-layer assembly 111-1 and a second two-layer assembly 111-2 having via-trace-via structures, where the first two-layer assembly 111-1 is coupled to the second two-layer assembly 111-2 by via-on-pad structures 1740. The package substrate may include a first signal line 1721, a second signal line 1722, a first ground plane 1731, a second ground plane 1732, and a power plane 1733. As shown in FIG. 17C, the first two-layer assembly 111-1 may be coupled to lower layers in the package substrate 1701 by via-on-pad structures 1741.

As shown in FIGS. 17B and 17C, the via-trace-via structures may provide power delivery with minimal reduction to IO density. By using the two-layer assemblies 111 in the high-density areas, a single trace may be sacrificed to make a vertical connection, whereas conventional vertical connections would require a via-on-pad structure and reduce the IO density more than the via-trace-via structures. For example, in order for the via-trace-via structures to enable a connection between the power plane 1733 and the die 134, a single IO line would need to be removed at a minimum L/S distance (e.g., if every eighth line is removed in an 8-row deep IO density, the IO density is only reduced by 12.5%). In order for conventional structures (e.g., via-on-pad structures) to enable a connection between the power plane and the die, the IO density is reduced by between 37.5% and 50% depending on the exposure tool alignment capability.

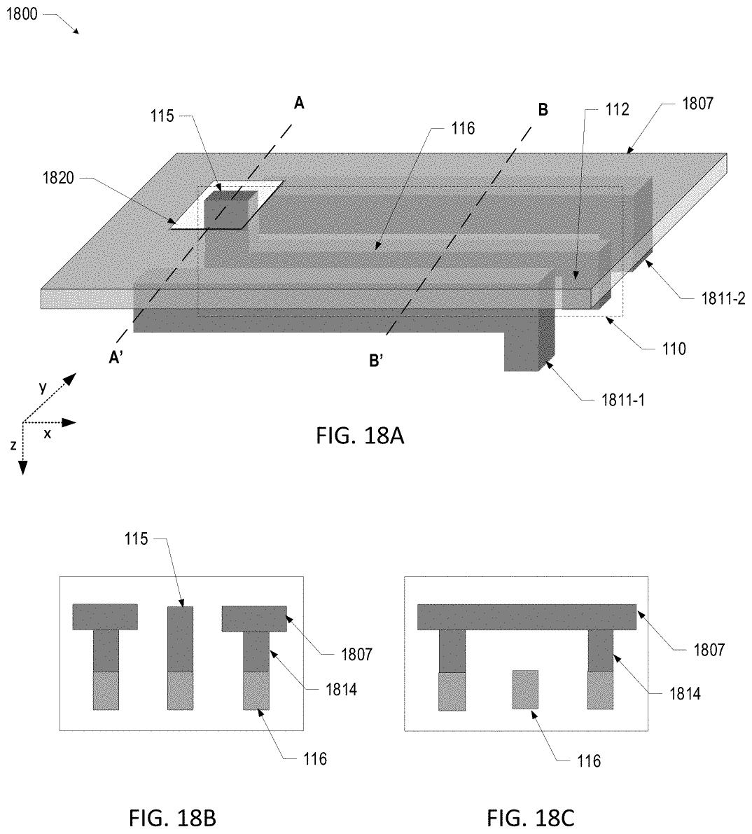

FIG. 18A is a perspective view of an assembly 1800 including a via-trace-via structure 110, in accordance with various embodiments. The assembly 1800 may include a via-trace-via structure 110, two via-trace structures 1811-1, 1811-2, and a top ground plane 1807. The via-trace-via structure 110 may include a first via 112, a trace 116, and a third via 115 where the third via 115 is not vertically aligned with the first via 112. The third via 115 may extend through an opening 1820 in the top ground plane 1807. The via-trace structures 1811 may include trench vias 1814 that extend along a length of the via-trace structures and couple to the top ground plane 1807. The trench vias 1814 when coupled to the top ground plane 1807 may reduce crosstalk and increase signal performance. FIG. 18B is a cross-sectional view of the assembly 1800 of FIG. 18A along the A-A′ line. FIG. 18C is a cross-sectional view of the assembly 1800 of FIG. 18A along the B-B′ line.

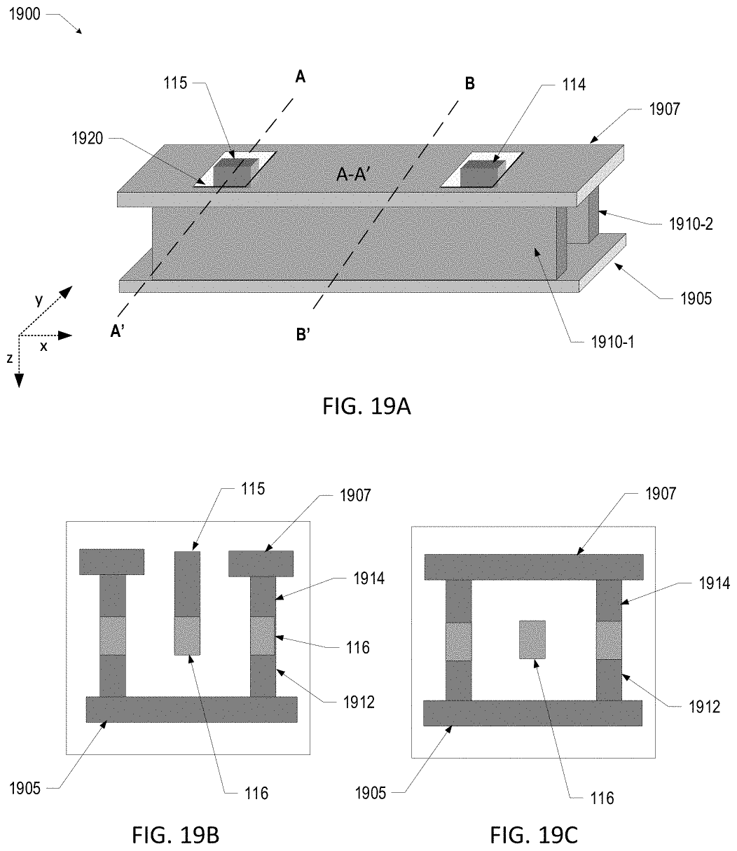

FIG. 19A is a perspective view of an assembly 1900 including a via-trace-via structure 110, in accordance with various embodiments. The assembly 1900 may include a via-trace-via structure 110, two via-trace-via structures 1910-1, 1910-2, a top ground plane 1907, and a bottom ground plane 1905. The via-trace-via structure 110 may include a trace 116, a second via 114, and a third via 115, and the first via 112 (e.g., the bottom via) may be omitted. The second via 114 and the third via 115 may extend through openings 1920 in the top ground plane 1907. As shown in FIG. 19B, the via-trace-via structure 1910 may include a first trench via 1912 that extends along a length of the via-trace-via structure 1910, a trace 116, and a second trench via 1914 that extends along a length of the via-trace-via structure 1910. The via-trace-via structure 1910 may be coupled to the bottom ground plane 1905 on a first surface and may be coupled to the top ground plane 1907 on an opposing second surface. The via-trace-via structures 1910 when coupled to the bottom and top ground planes 1905, 1907 may form a rectilinear coaxial waveguide, which may reduce signal loss and enable maximal IO bandwidth. FIG. 19B is a cross-sectional view of the assembly 1900 of FIG. 19A along the A-A′ line. FIG. 19C is a cross-sectional view of the assembly 1900 of FIG. 19A along the B-B′ line.

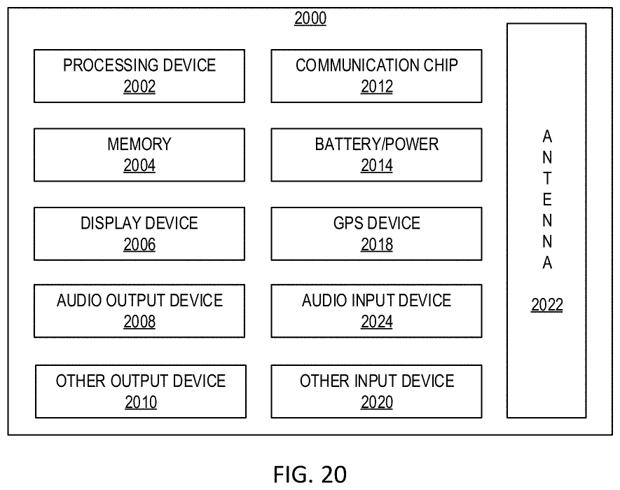

The microelectronic assemblies disclosed herein may be included in any suitable electronic component. FIG. 20 is a block diagram of an example electrical device 2000 that may include one or more of the microelectronic assemblies disclosed herein. A number of components are illustrated in FIG. 20 as included in the electrical device 2000, but any one or more of these components may be omitted or duplicated, as suitable for the application. In some embodiments, some or all of the components included in the electrical device 2000 may be attached to one or more motherboards. In some embodiments, some or all of these components are fabricated onto a single system-on-a-chip (SoC) die.

Additionally, in various embodiments, the electrical device 2000 may not include one or more of the components illustrated in FIG. 20, but the electrical device 2000 may include interface circuitry for coupling to the one or more components. For example, the electrical device 2000 may not include a display device 2006, but may include display device interface circuitry (e.g., a connector and driver circuitry) to which a display device 2006 may be coupled. In another set of examples, the electrical device 2000 may not include an audio input device 2024 or an audio output device 2008, but may include audio input or output device interface circuitry (e.g., connectors and supporting circuitry) to which an audio input device 2024 or audio output device 2008 may be coupled.

The electrical device 2000 may include a processing device 2002 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2002 may include one or more digital signal processors (DSPs), application-specific integrated circuits (ASICs), CPUs, GPUs, cryptoprocessors (specialized processors that execute cryptographic algorithms within hardware), server processors, or any other suitable processing devices. The electrical device 2000 may include a memory 2004, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, the memory 2004 may include memory that shares a die with the processing device 2002. This memory may be used as cache memory and may include embedded dynamic random access memory (eDRAM) or spin transfer torque magnetic random access memory (STT-M RAM).

In some embodiments, the electrical device 2000 may include a communication chip 2012 (e.g., one or more communication chips). For example, the communication chip 2012 may be configured for managing wireless communications for the transfer of data to and from the electrical device 2000. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2012 may implement any of a number of wireless standards or protocols, including but not limited to Institute of Electrical and Electronic Engineers (IEEE) standards including Wi-Fi (IEEE 802.11 family), IEEE 802.16 standards (e.g., IEEE 802.16-2005 Amendment), 3rd Generation Partnership Project (3GPP) Long-Term Evolution (LTE), 5G, 5G New Radio, along with any amendments, updates, and/or revisions (e.g., advanced LTE project, ultra-mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2012 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2012 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2012 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2012 may operate in accordance with other wireless protocols in other embodiments. The electrical device 2000 may include an antenna 2022 to facilitate wireless communications and/or to receive other wireless communications (such as AM or FM radio transmissions).

In some embodiments, the communication chip 2012 may manage wired communications, such as electrical, optical, or any other suitable communication protocols (e.g., the Ethernet). As noted above, the communication chip 2012 may include multiple communication chips. For instance, a first communication chip 2012 may be dedicated to shorter-range wireless communications such as Wi-Fi or Bluetooth, and a second communication chip 2012 may be dedicated to longer-range wireless communications such as global positioning system (GPS), EDGE, GPRS, CDMA, WiMAX, LTE, EV-DO, or others. In some embodiments, a first communication chip 2012 may be dedicated to wireless communications, and a second communication chip 2012 may be dedicated to wired communications.

The electrical device 2000 may include battery/power circuitry 2014. The battery/power circuitry 2014 may include one or more energy storage devices (e.g., batteries or capacitors) and/or circuitry for coupling components of the electrical device 2000 to an energy source separate from the electrical device 2000 (e.g., AC line power).

The electrical device 2000 may include a display device 2006 (or corresponding interface circuitry, as discussed above). The display device 2006 may include any visual indicators, such as a heads-up display, a computer monitor, a projector, a touchscreen display, a liquid crystal display (LCD), a light-emitting diode display, or a flat panel display.

The electrical device 2000 may include an audio output device 2008 (or corresponding interface circuitry, as discussed above). The audio output device 2008 may include any device that generates an audible indicator, such as speakers, headsets, or earbuds.

The electrical device 2000 may include an audio input device 2024 (or corresponding interface circuitry, as discussed above). The audio input device 2024 may include any device that generates a signal representative of a sound, such as microphones, microphone arrays, or digital instruments (e.g., instruments having a musical instrument digital interface (MIDI) output).

The electrical device 2000 may include a GPS device 2018 (or corresponding interface circuitry, as discussed above). The GPS device 2018 may be in communication with a satellite-based system and may receive a location of the electrical device 2000, as known in the art.

The electrical device 2000 may include another output device 2010 (or corresponding interface circuitry, as discussed above). Examples of the other output device 2010 may include an audio codec, a video codec, a printer, a wired or wireless transmitter for providing information to other devices, or an additional storage device.

The electrical device 2000 may include another input device 2020 (or corresponding interface circuitry, as discussed above). Examples of the other input device 2020 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 2000 may have any desired form factor, such as a hand-held or portable computing device (e.g., a cell phone, a smart phone, a mobile internet device, a music player, a tablet computer, a laptop computer, a netbook computer, an ultrabook computer, a personal digital assistant (PDA), an ultra-mobile personal computer, etc.), a desktop electrical device, a server device or other networked computing component, a printer, a scanner, a monitor, a set-top box, an entertainment control unit, a vehicle control unit, a digital camera, a digital video recorder, or a wearable electrical/computing device. In some embodiments, the electrical device 2000 may be any other electronic device that processes data.

The following paragraphs provide various examples of the embodiments disclosed herein.

Example 1 is a microelectronic assembly, including: a first conductive via having a first footprint in a first dielectric layer; a conductive trace having a first surface and an opposing second surface, wherein the first conductive via is in contact with the first surface of the conductive trace; and a second conductive via having a second footprint in a second dielectric layer, wherein the second dielectric layer is on the first dielectric layer, wherein the second conductive via is in contact with the second surface of the conductive trace, wherein the second conductive via is vertically aligned with the first conductive via, and wherein the second footprint extends beyond the first footprint on a single side by between 0.1 um and 7.5 um.

Example 2 may include the subject matter of Example 1, and may further include: a seed layer on the first surface of the conductive trace.

Example 3 may include the subject matter of Example 1, and may further specify that a material of the first dielectric layer is different from a material of the second dielectric layer.

Example 4 may include the subject matter of Example 3, and may further specify that the first dielectric layer includes a photo-imageable dielectric.

Example 5 may include the subject matter of Example 1, and may further specify that the second dielectric layer includes an organic material.

Example 6 may include the subject matter of Example 1, and may further specify that the conductive trace is a first conductive trace, and may further include: a third conductive via in the first dielectric layer; a second conductive trace having a first surface and an opposing second surface, wherein the third conductive via is in contact with the first surface of the second conductive trace; and a fourth conductive via in the second dielectric layer, wherein the fourth conductive via is in contact with the second surface of the second conductive trace, and wherein an inter-trace spacing between the first conductive trace and the second conductive trace is between 0.5 um and 25 um.

Example 7 may include the subject matter of Example 1, and may further include: a fifth conductive via in the second dielectric layer, wherein the fifth conductive via is in contact with the second surface of the conductive trace, and wherein the fifth conductive via is not vertically aligned with the first conductive via.

Example 8 may include the subject matter of Example 1, and may further specify that the first dielectric layer and the second dielectric layer are on a surface of a die.

Example 9 may include the subject matter of Example 1, and may further specify that the first dielectric layer and the second dielectric layer are on a surface of an interposer.

Example 10 may include the subject matter of Example 1, and may further specify that the second conductive via is coupled to a die.

Example 11 may include the subject matter of Example 1, and may further specify that the microelectronic assembly is included in a portable computing device.

Example 12 is an integrated circuit (IC) package substrate, including: a conductive trace having a first surface and an opposing second surface; a first conductive via in a first dielectric layer, wherein the first conductive via is in contact with the first surface of the conductive trace; and a second conductive via in a second dielectric layer, wherein the second conductive via is in contact with the second surface of the conductive trace, wherein the second dielectric layer is on the first dielectric layer, and wherein the first conductive via, the second conductive via, and the conductive trace have a same width between 0.5 um and 25 um.

Example 13 may include the subject matter of Example 12, and may further specify that the second conductive via is vertically aligned with the first conductive via.

Example 14 may include the subject matter of Example 12, and may further specify that the second conductive via is not vertically aligned with the first conductive via.

Example 15 may include the subject matter of Example 12, and may further specify that the first dielectric layer includes a photo-imageable dielectric.

Example 16 may include the subject matter of Example 12, and may further specify that the first conductive via, the conductive trace, and the second conductive via include copper.

Example 17 may include the subject matter of Example 12, and may further specify that the first conductive via is coupled to a ground plane.

Example 18 may include the subject matter of Example 12, and may further specify that the first conductive via is coupled to a power plane.

Example 19 may include the subject matter of Example 12, and may further specify that the first conductive via is coupled to a first ground plane and the second conductive via is coupled to a second ground plane.

Example 20 may include the subject matter of Example 12, and may further include: a die, wherein the die is coupled to the second conductive via by first-level interconnects.

Example 21 may include the subject matter of Example 12, and may further include: a third conductive via in the second dielectric layer, wherein the third conductive via is in contact with the second surface of the conductive trace, and wherein the third conductive via has a width that is the same as the width of the first conductive via, the second conductive via, and the conductive trace.

Example 22 is a method of manufacturing a microelectronic assembly, including: depositing a photo-imageable dielectric (PID) on a first seed layer on a substrate; forming a second seed layer on the PID; depositing and patterning a first photoresist on the second seed layer, wherein patterning the first photoresist removes a region of the first photoresist to expose a first portion of the second seed layer; removing the first portion of the second seed layer; removing the first photoresist; depositing a second photoresist on the second seed layer; performing a first patterning of the second photoresist, wherein the first patterning removes a first region of the second photoresist to expose a second portion of the second seed layer and removes a portion of the PID, exposed by removing the first portion of the second seed layer, to expose a portion of the first seed layer; depositing a first conductive layer on the portion of the first seed layer; depositing a second conductive layer on the first portion and the second portion of the second seed layer; performing a second patterning of the second photoresist, wherein the second patterning removes a second region of the second photoresist to expose a third portion of the second seed layer; and depositing a third conductive layer on the first portion, the second portion, and the third portion of the second seed layer.

Example 23 may include the subject matter of Example 22, and may further specify that the first, second, and third conductive layers form a first via in the PID, a trace coupled on a first surface to the first via, and a second via and a third via coupled to an opposing second surface of the trace.

Example 24 may include the subject matter of Example 22, and may further specify that the second photoresist is a tunable photoresist.

Example 25 may include the subject matter of Example 24, and may further specify that patterning the second photoresist includes: exposing the first region of the second photoresist to at least a first wavelength; and exposing the second region of the second photoresist to at least a second wavelength.

Example 26 may include the subject matter of Example 24, and may further specify that patterning the second photoresist includes: exposing the first region of the second photoresist to a first light dose; and exposing the second region of the second photoresist to a second light dose.

Example 27 may include the subject matter of Example 22, and may further include: removing the second photoresist.

Example 28 may include the subject matter of Example 27, and may further include: removing the portions of the second seed layer that are exposed after removing the second photoresist.

Example 29 is a method of manufacturing a microelectronic assembly, including: depositing a photo-imageable dielectric (PID) on a first seed layer on a substrate; forming a second seed layer on the PID; depositing and patterning a first photoresist on the second seed layer, wherein patterning the first photoresist removes a region of the first photoresist to expose a first portion of the second seed layer; removing the first portion of the second seed layer; removing the first photoresist; depositing a second photoresist on the second seed layer; performing a first patterning of the second photoresist, wherein the first patterning removes a first region of the second photoresist to expose a second portion of the second seed layer and removes a portion of the PID, exposed by removing the first portion of the second seed layer, to expose a portion of the first seed layer; depositing a first conductive layer on the second portion of the second seed layer; performing a second patterning of the second photoresist, wherein the second patterning removes a second region of the second photoresist to expose a third portion of the second seed layer; and depositing a second conductive layer on the portion of the first seed layer, and on the first, the second, and the third portions of the second seed layer.

Example 30 may include the subject matter of Example 29, and may further specify that the first conductive layer and the second conductive layer are deposited using an electroplating process.

Example 31 may include the subject matter of Example 29, and may further specify that the first and second conductive layers form a first via in the PID, a trace coupled on a first surface to the first via, and a second via coupled to an opposing second surface of the trace.

Example 32 may include the subject matter of Example 29, and may further specify that the second photoresist is a tunable photoresist.

Example 33 may include the subject matter of Example 32, and may further specify that patterning the second photoresist includes: exposing the first region of the second photoresist to at least a first wavelength; and exposing the second region of the second photoresist to at least a second wavelength.

Example 34 may include the subject matter of Example 32, and may further specify that patterning the second photoresist includes: exposing the first region of the second photoresist to a first light dose; and exposing the second region of the second photoresist to a second light dose.

Example 35 may include the subject matter of Example 29, and may further include: removing the second photoresist.

Example 36 may include the subject matter of Example 35, and may further include: removing the portions of the second seed layer that are exposed after removing the second photoresist.

Example 37 is a computing device, including: a microelectronic assembly, including: a conductive trace having a first surface and an opposing second surface; a first conductive via in a first dielectric layer, wherein the first conductive via is in contact with the first surface of the conductive trace; and a second conductive via in a second dielectric layer, wherein the second conductive via is in contact with the second surface of the conductive trace, wherein the second dielectric layer is on the first dielectric layer, and wherein the first conductive via, the second conductive via, and the conductive trace have a same width between 0.5 um and 25 um; a die, wherein the die is coupled to the second conductive via by first-level interconnects; and a circuit board coupled to the microelectronic assembly.

Example 38 may include the subject matter of Example 37, and may further specify that the second conductive via is vertically aligned with the first conductive via.

Example 39 may include the subject matter of Example 37, and may further specify that the second conductive via is not vertically aligned with the first conductive via.

Example 40 may include the subject matter of Example 37, and may further specify that a material of the first dielectric layer is different from a material of the second dielectric layer.

Example 41 may include the subject matter of Example 40, and may further specify that the first dielectric layer includes a photo-imageable dielectric.

Example 42 may include the subject matter of Example 40, and may further specify that the second dielectric layer includes an organic material.

Example 43 may include the subject matter of Example 37, and may further specify that the first conductive via is coupled to a ground plane.

Example 44 may include the subject matter of Example 37, and may further specify that the circuit board is a motherboard.

Example 45 may include the subject matter of Example 37, and may further include: an antenna coupled to the circuit board.

Example 46 may include the subject matter of any of Examples 37-44, and may further specify that the computing device is a server device.

Example 47 may include the subject matter of any of Examples 37-44, and may further specify that the computing device is a portable computing device.

Example 48 may include the subject matter of any of Examples 37-44, and may further specify that the computing device is a wearable computing device.

1. A microelectronic assembly, comprising:
a first conductive via having a first footprint in a first dielectric layer;
a conductive trace having a first surface and an opposing second surface, wherein the first conductive via is in contact with the first surface of the conductive trace; and
a second conductive via having a second footprint in a second dielectric layer, wherein the second dielectric layer is on the first dielectric layer, wherein the second conductive via is in contact with the second surface of the conductive trace, wherein the second conductive via is vertically aligned with the first conductive via, and wherein the second footprint extends beyond the first footprint on a single side by between 0.1 um and 7.5 um.

2. The microelectronic assembly of claim 1, further comprising:
a seed layer on the first surface of the conductive trace.

3. The microelectronic assembly of claim 1, wherein a material of the first dielectric layer is different from a material of the second dielectric layer.

4. The microelectronic assembly of claim 3, wherein the first dielectric layer includes a photo-imageable dielectric.

5. The microelectronic assembly of claim 1, wherein the second dielectric layer includes an organic material.

6. The microelectronic assembly of claim 1, wherein the conductive trace is a first conductive trace, further comprising:
a third conductive via in the first dielectric layer;
a second conductive trace having a first surface and an opposing second surface, wherein the third conductive via is in contact with the first surface of the second conductive trace; and
a fourth conductive via in the second dielectric layer, wherein the fourth conductive via is in contact with the second surface of the second conductive trace, and wherein an inter-trace spacing between the first conductive trace and the second conductive trace is between 0.5 um and 25 um.

7. The microelectronic assembly of claim 1, further comprising:
a fifth conductive via in the second dielectric layer, wherein the fifth conductive via is in contact with the second surface of the conductive trace, and wherein the fifth conductive via is not vertically aligned with the first conductive via.

8. The microelectronic assembly of claim 1, wherein the first dielectric layer and the second dielectric layer are on a surface of a die.

9. The microelectronic assembly of claim 1, wherein the first dielectric layer and the second dielectric layer are on a surface of an interposer.

10. An integrated circuit (IC) package substrate, comprising:
a conductive trace having a first surface and an opposing second surface;
a first conductive via in a first dielectric layer, wherein the first conductive via is in contact with the first surface of the conductive trace; and
a second conductive via in a second dielectric layer, wherein the second conductive via is in contact with the second surface of the conductive trace, wherein the second dielectric layer is on the first dielectric layer, and wherein the first conductive via, the second conductive via, and the conductive trace have a same width between 0.5 um and 25 um.

11. The IC package substrate of claim 10, wherein the second conductive via is vertically aligned with the first conductive via.

12. The IC package substrate of claim 10, wherein the second conductive via is not vertically aligned with the first conductive via.

13. The IC package substrate of claim 10, wherein the first dielectric layer includes a photo-imageable dielectric.

14. The IC package substrate of claim 10, wherein the first conductive via is coupled to a ground plane.

15. The IC package substrate of claim 10, wherein the first conductive via is coupled to a power plane.

16. The IC package substrate of claim 10, wherein the first conductive via is coupled to a first ground plane and the second conductive via is coupled to a second ground plane.

17. A computing device, comprising:
a microelectronic assembly, comprising:
a conductive trace having a first surface and an opposing second surface;
a first conductive via in a first dielectric layer, wherein the first conductive via is in contact with the first surface of the conductive trace; and
a second conductive via in a second dielectric layer, wherein the second conductive via is in contact with the second surface of the conductive trace, wherein the second dielectric layer is on the first dielectric layer, and wherein the first conductive via, the second conductive via, and the conductive trace have a same width between 0.5 um and 25 um;
a die, wherein the die is coupled to the second conductive via by first-level interconnects; and
a circuit board coupled to the microelectronic assembly.

18. The computing device of claim 17, wherein the first dielectric layer includes a photo-imageable dielectric.

19. The computing device of claim 17, wherein the circuit board is a motherboard.

20. The computing device of claim 17, wherein the computing device is a portable computing device.
